(19) United States
(12) Patent Application Publication
(10) Pub. No.: US 2026/0253524 A1
(43) Pub. Date: Aug. 27, 2026

(54) DISPLAY DEVICE, AND CONTROL ASSEMBLY THEREOF AND DRIVING METHOD THEREFOR

(71) Applicants: Beijing BOE Display Technology Co., Ltd., Beijing (CN); BOE TECHNOLOGY GROUP CO., LTD., Beijing (CN)

(72) Inventors: Zhiming MENG, Beijing (CN); Jianzi HE, Beijing (CN); Junning SU, Beijing (CN); Yucheng ZHAO, Beijing (CN); Minghan LI, Beijing (CN); He CHAO, Beijing (CN); Jialing LV, Beijing (CN); Jianyang LIU, Beijing (CN); Hanzhang NIU, Beijing (CN); Hao SONG, Beijing (CN)

(21) Appl. No.: 18/845,464

(22) PCT Filed: Oct. 31, 2022
(86) PCT No.: PCT/CN2022/128760

§ 371 Date: Sep. 10, 2024

(51) Int. Cl. G09G 3/20

(52) U.S. Cl. CPC G09G 3/2003; G09G 2310/027

(57) ABSTRACT

Provided are a display device, and a control assembly thereof and a driving method therefor, relating to the technical field of display. A display panel of the display device is a display panel having a sub-pixel layout. The driving method for the display device comprises: acquiring picture data; acquiring a feature boundary area (BA) according to the gray scale of pixels (Pix) in the picture data; determining a transition area (TA) corresponding to the feature BA; correcting the gray scale of at least some of pixels (Pix) of the TA corresponding to the feature BA; and driving the display panel according to a correction result of the gray scale of at least some of pixels (Pix) of the TA corresponding to the feature BA.

### TECHNICAL FIELD

The present disclosure relates to the field of display technology, and specifically to a display device, a control component thereof and a driving method.

### BACKGROUND

When a display device in which sub-pixels are interleaved displays an image having a light-dark boundary, the vertical lines (lines in the column direction) of the light-dark boundary of the image may appear visibly jagged, which reduces the quality of the displayed image.

It is to be noted that the information disclosed in the above-described background section is intended only to enhance the understanding of the background of the present disclosure, and thus may include information that does not constitute prior art known to those of ordinary skill in the art.

### SUMMARY

It is an object of the present disclosure to overcome the above-mentioned deficiencies in the related art, and to provide a display device and a control component and a driving method thereof to improve the quality of a display screen.

According to a first aspect of the present disclosure, there is provided a display device capable of displaying a target picture based on picture data of a received initial picture; wherein the display device is configured to: adjust, when the initial picture includes at least one feature boundary area, brightnesses of at least some pixels of the feature boundary area to generate a target picture;
where the feature boundary area includes a plurality of feature pixel groups sequentially adjacent along a column direction; the feature pixel group includes a first feature pixel and a second feature pixel which are adjacent in a same row, and a brightness difference between the first feature pixel and the second feature pixel is greater than or equal to a brightness threshold; and where individual first feature pixels in a same feature boundary area are provided in a same column; and
a difference between a brightness of the first feature pixel and a brightness of the second feature pixel in the target picture at positions corresponding one-to-one with pixels in the feature boundary area of the initial picture is less than a difference between a brightness of the first feature pixel and a brightness of the second feature pixel in the initial picture.

According to an embodiment of the present disclosure, the display device includes a display panel; the display panel includes a plurality of pixels distributed in an array, and any one of the pixels includes a plurality of sub-pixels of different colors disposed adjacent along a row direction; individual sub-pixels are arranged in a plurality of columns of sub-pixels; and in any one of the columns of sub-pixels, two adjacent sub-pixels are different in color.

According to an embodiment of the present disclosure, a number of feature pixel groups in any one of the feature boundary areas is not less than a feature number threshold; and the feature number threshold is not less than 5.

According to an embodiment of the present disclosure, the brightness threshold is not less than 50 nits.

According to an embodiment of the present disclosure, gray scales for individual sub-pixels of the first feature pixel are same and gray scales for individual sub-pixels of the second feature pixel are same in the initial picture.

According to an embodiment of the present disclosure, gray scales of the first feature pixels are same and gray scales of the second feature pixels are same in at least one of the feature boundary areas.

According to an embodiment of the present disclosure, the display device is a spliced display device; the display device includes a plurality of display modules arranged in matrix and spliced together, and the display modules include display panels.

According to an embodiment of the present disclosure, on at least one side of the display panel, a distance between an edge of a display area of the display panel and an edge of the display panel on this side is not greater than 2 millimeters.

According to an embodiment of the present disclosure, the brightness difference between the first feature pixel and the second feature pixel is a theoretical maximum brightness difference between the first feature pixel and the second feature pixel.

According to a second aspect of the present disclosure, there is provided a control component for a display device, the display device further includes a display panel; the display panel includes a plurality of pixels distributed in an array, and any one of the pixels includes a plurality of sub-pixels of different colors disposed adjacent along a row direction; individual sub-pixels are arranged in a plurality of columns of sub-pixels; and in any one of the columns of sub-pixels, two adjacent sub-pixels are different in color;
the control component includes a data handling unit, and the data handling unit includes:
a data caching unit configured to obtain picture data;
a transition area determining unit configured to obtain a feature boundary area based on gray scales of pixels in the picture data; the feature boundary area includes a plurality of feature pixel groups sequentially adjacent along a column direction; the feature pixel group includes a first feature pixel and a second feature pixel which are adjacent in a same row and a brightness difference between the first feature pixel and the second feature pixel is greater than or equal to a brightness threshold; individual first feature pixels in a same feature boundary area are provided in a same column; the transition area determining unit is further configured to determine a transition area corresponding to the feature boundary area; the transition area corresponding to the feature boundary area includes at least a first transition area, the first transition area includes individual first feature pixels and/or individual second feature pixels of the feature boundary area;
a transition algorithm unit configured to correct gray scales of at least some of pixels of the transition area corresponding to the feature boundary area, such that, after correction, a difference between a brightness of the first feature pixel and a brightness of the second feature pixel in the feature boundary area is less than a difference between a brightness of the first feature pixel before the correction and a brightness of the second feature pixel before the correction; and
a data outputting unit configured to drive the display panel based on a result of correcting the gray scales of at least some of the pixels in the transition area corresponding to the feature boundary area.

According to an embodiment of the present disclosure, the transition area determining unit includes:
a data comparing unit configured to compare brightnesses of two pixels adjacent in a same row to determine whether the two pixels adjacent in the same row are considered as a feature pixel group;
a data recording and accumulating unit configured to record a number of feature pixel groups adjacent in a same column, and determine whether these feature pixel groups adjacent in the same column form a feature boundary area.

According to an embodiment of the present disclosure, the data caching unit is configured to cache the initial picture data;
the data handling unit further includes a sub-pixel adjusting unit, the sub-pixel adjusting unit is configured to obtain post-adjustment picture data by adjusting an arrangement sequence of gray scales of at least some of the sub-pixels in the initial picture data according to an arrangement of the sub-pixels of the display panel;
the data caching unit is further configured to update the initial picture data to the post-adjustment picture data based on the post-adjustment picture data of the sub-pixel adjusting unit;
the transition area determining unit is configured to obtain the feature boundary area based on gray scales of pixels in the post-adjustment picture data.

According to an embodiment of the present disclosure, the data handling unit is a SOC chip or an FPGA.

According to a third aspect of the present disclosure, there is provided a method for driving a display device, where a display panel of the display device includes a plurality of pixels distributed in an array, and any one of the pixels includes a plurality of sub-pixels of different colors disposed adjacent along a row direction; individual sub-pixels are arranged in a plurality of columns of sub-pixels; and in any one of the sub-pixel columns, two adjacent sub-pixels are different in color;
the method for driving the display device includes:
obtaining picture data;
obtaining a feature boundary area based on gray scales of pixels in the picture data; the feature boundary area includes a plurality of feature pixel groups sequentially adjacent along a column direction; the feature pixel group includes a first feature pixel and a second feature pixel which are adjacent in a same row, and a brightness difference between the first feature pixel and the second feature pixel is greater than or equal to a brightness threshold; individual first feature pixels in a same feature boundary area are provided in a same column;
determining a transition area corresponding to the feature boundary area; the transition area corresponding to the feature boundary area includes at least a first transition area, the first transition area includes individual first feature pixels and/or individual second feature pixels of the feature boundary area;
correcting gray scales of at least some of pixels of the transition area corresponding to the feature boundary area, such that, after correction, a difference between a brightness of the first feature pixel and a brightness of the second feature pixel in the feature boundary area is less than a difference between a brightness of the first feature pixel before the correction and a brightness of the second feature pixel before the correction; and
driving the display panel based on a result of correcting the gray scales of at least some of the pixels in the transition area corresponding to the feature boundary area.

According to an embodiment of the present disclosure, a number of feature pixel groups in any one of the feature boundary areas is not less than a feature number threshold.

According to an embodiment of the present disclosure, the feature number threshold is not less than 5; and the brightness threshold is in the range of 40 to 1000 nits.

According to an embodiment of the present disclosure, obtaining the feature boundary area based on the gray scales of the pixels in the picture data further includes:
causing the feature boundary area to have a homochromatic contiguous area, the homochromatic contiguous area is adjacent to at least one column of pixels in the feature boundary area and has same color and gray scale as the at least one column of pixels in the feature boundary area;
determining the transition area corresponding to the feature boundary area includes:
determining the transition area corresponding to the feature boundary area based on the feature boundary area and the homochromatic contiguous area of the feature boundary area.

According to an embodiment of the present disclosure, the homochromatic contiguous area of the feature boundary area includes at least one of a first homochromatic contiguous area and a second homochromatic contiguous area;
the first homochromatic contiguous area includes first homochromatic pixel groups corresponding one-to-one with individual feature pixel groups of the feature boundary area; the first homochromatic pixel group is adjacent to the first feature pixel of a corresponding feature pixel group in a same row and is of same color and grayscale as the first feature pixel, and the first homochromatic pixel group includes one or more pixels;
the second homochromatic contiguous area includes second homochromatic pixel groups corresponding one-to-one with individual feature pixel groups of the feature boundary area; the second homochromatic pixel group is adjacent to the second feature pixel of a corresponding the feature pixel group in a same row and is of same color and gray scale as the second feature pixel, and the second homochromatic pixel group includes one or more pixels.

According to an embodiment of the present disclosure, when the homochromatic contiguous area of the feature boundary area includes a first homochromatic contiguous area, determining the transition area corresponding to the feature boundary area includes:
determining that the transition area corresponding to the feature boundary area includes individual first feature pixels of the feature boundary area;
correcting the gray scales of at least some of the pixels of the transition area corresponding to the feature boundary area includes:
obtaining corrected gray scales of the individual first feature pixels of the feature boundary area by reducing gray scales of the individual first feature pixels; the corrected gray scale of the first feature pixel is greater than a gray scale of the second feature pixel in a same feature pixel group.

According to an embodiment of the present disclosure, correcting the gray scales of at least some of the pixels of the transition area corresponding to the feature boundary area includes:
obtaining corrected gray scales Gn(Pix1) of individual first feature pixels of the feature boundary area by reducing gray scales of the individual first feature pixels, and

G(Pix2)+0.3*(G(Pix1)−G(Pix2))<Gn(Pix1)<G(Pix1)−0.3*(G(Pix1)−G(Pix2));
wherein G(Pix1) is a gray scale of the first feature pixel; and G(Pix2) is a gray scale of the second feature pixel.

According to an embodiment of the present disclosure, when the homochromatic contiguous area of the feature boundary area includes a first homochromatic contiguous area and the first homochromatic contiguous area includes a plurality of columns of pixels, determining the transition area corresponding to the feature boundary area includes:
determining that the transition area corresponding to the feature boundary area includes a first transition area and a second transition area; the first transition area includes individual first feature pixels of the feature boundary area; and the second transition area includes at least one column of pixels in the first homochromatic contiguous area adjacent to the first transition area, and at least one column of pixels in the first homochromatic contiguous area does not belong to the second transition area;
correcting the gray scales of at least some of the pixels in the transition area corresponding to the feature boundary area includes:
obtaining corrected gray scales of individual pixels by reducing the gray scales of the individual pixels in the transition area, wherein the corrected gray scales of the individual pixels in any row in the transition area decreases sequentially along a direction pointing from the first homochromatic contiguous area to the feature boundary area, and the corrected gray scale of the first feature pixel is greater than a gray scale of the second feature pixel.

According to an embodiment of the present disclosure, correcting the gray scales of at least some of the pixels in the transition area corresponding to the feature boundary area includes:
determining a corrected gray scale of any one pixel in the transition area according to the following formula:

Gn(q)=round(G(Pix1)−q*((G(Pix1)−G(Pix2))/(Q+1));
where Gn(q) is a corrected gray scale of a qth column of pixels P(q) in the transition area along a direction pointing from the first homochromatic contiguous area to the feature boundary area; G(Pix1) is a gray scale of the first feature pixel which is in a same row with pixel P(q); G(Pix2) is a gray scale of the second feature pixel which is in a same row with pixel P(q); Q is a number of columns of pixels included in the transition area, Q is a positive integer not less than 2; and q is a positive integer from 1 to Q.

According to an embodiment of the present disclosure, when the homochromatic contiguous area of the feature boundary area includes a second homochromatic contiguous area, determining the transition area corresponding to the feature boundary area includes:
determining that the transition area corresponding to the feature boundary area includes individual second feature pixels of the feature boundary area;
correcting the gray scales of at least some of the pixels of the transition area corresponding to the feature boundary area includes:
obtaining corrected gray scales of the individual second feature pixels by increasing gray scales of the individual second feature pixels of the feature boundary area; the corrected gray scale of the second feature pixel is less than a gray scale of the first feature pixel in a same feature pixel group.

According to an embodiment of the present disclosure, correcting the gray scales of at least some of the pixels of the transition area corresponding to the feature boundary area includes:
obtaining corrected gray scales Gn(Pix2) of individual second feature pixels of the feature boundary area by increasing gray scales of the individual second feature pixels, and

$$G ( P i x 2 ) + 0 . {3}^{*} ( G ( P i x 1 ) - G ( P i x 2 ) ) < G n ( P i x 2 ) < G ( Pix 1 ) - {0.3}^{*} ( G ( P i x 1 ) - G ( P i x 2 ) ) ;$$

where G(Pix1) is a gray scale of the first feature pixel; and G(Pix2) is a gray scale of the second feature pixel.

According to an embodiment of the present disclosure, when the homochromatic contiguous area of the feature boundary area includes a second homochromatic contiguous area and the second homochromatic contiguous area includes a plurality of columns of pixels, determining the transition area corresponding to the feature boundary area includes:
determining that the transition area corresponding to the feature boundary area includes a first transition area and a third transition area; the first transition area includes individual second feature pixels of the feature boundary area; and the third transition area includes at least one column of pixels in the second homochromatic contiguous area adjacent to the first transition area, and at least one column of pixels in the second homochromatic contiguous area does not belong to the third transition area;
correcting the gray scales of at least some of the pixels in the transition area corresponding to the feature boundary area includes:
obtaining corrected gray scales of individual pixels in the transition area by increasing gray scales of the individual pixels, and the corrected gray scales of the individual pixels in any row of the transition area increases sequentially along a direction pointing from the second homochromatic contiguous area to the feature boundary area, and the corrected gray scale of the second feature pixel is less than a gray scale of the first feature pixel.

According to an embodiment of the present disclosure, correcting the gray scales of at least some of the pixels in the transition area corresponding to the feature boundary area includes:
determining a corrected gray scale for any one pixel in the transition area according to the following formula:

$$Gn ( t ) = round ( G ( Pix 1 ) - {t}^{*} ( ( G ( P i x 1 ) - G ( P i x 2 ) ) / ( T + 1 ) ) ;$$

where Gn(t) is a corrected gray scale of a t-th column of pixels P(t) in the transition area along a direction pointing from the second homochromatic contiguous area to the feature boundary area; G(Pix1) is a gray scale of the first feature pixel which is in a same row with pixel P(t); G(Pix2) is a gray scale of the second feature pixel which is in a same row with pixel P(t); T is a number of columns of pixels included in the transition area, T is a positive integer not less than 2; and t is a positive integer from 1 to T.

It should be understood that the above general description and the detailed description that follows are exemplary and explanatory only and do not limit the present disclosure.

### BRIEF DESCRIPTION OF THE DRAWINGS

The accompanying drawings herein are incorporated into and form a part of the specification, illustrate embodiments consistent with the present disclosure, and are used in conjunction with the specification to explain the principles of the present disclosure. Obviously, the accompanying drawings in the following description are only some of the embodiments of the present disclosure, and other accompanying drawings may be obtained from these drawings without creative labor for those of ordinary skill in the art.

FIG. 1 shows a schematic diagram of a structure of a display device in an embodiment of the present disclosure.

FIG. 2 shows a schematic diagram of a structure of a liquid crystal display panel in an embodiment of the present disclosure.

FIG. 3 shows a schematic structural diagram of a light board of a backlight unit in an embodiment of the present disclosure.

FIG. 4 shows a schematic diagram of a structure of a display panel including a plurality of display sub-panels in an embodiment of the present disclosure.

FIG. 5 is a schematic diagram of a way of arranging sub-pixels in pixels on a display panel in the related art.

FIG. 6 is a schematic diagram of sub-pixels of the display panel near a border of the display device being obscured by the border of the display device in the related art.

FIG. 7 shows a schematic diagram of a way of arranging sub-pixels in pixels on a display panel in an embodiment of the present disclosure.

FIG. 8 shows a schematic diagram of sub-pixels of the display panel near a border of the display device being obscured by the border of the display device in an embodiment of the present disclosure.

FIG. 9-1 shows a schematic diagram of an initial picture having a light-dark border area in an embodiment of the present disclosure.

FIG. 9-2 shows a schematic diagram of a target picture having a light-dark border area in an embodiment of the present disclosure.

FIG. 10 shows a schematic diagram of a border area including two columns of pixels in the light-dark border area corresponding to the vertical line FIGA at the light-dark border in an embodiment of the present disclosure.

FIG. 11 shows a schematic diagram of a border area including two columns of pixels in the light-dark border area corresponding to the vertical line FIGB at the light-dark border in an embodiment of the present disclosure.

FIG. 12 is a schematic diagram of a processing result of the data processing module on the picture data in an embodiment of the present disclosure.

FIG. 13 is a schematic diagram of a procedure of processing the picture data by the data processing module in an embodiment of the present disclosure.

FIG. 14 shows a schematic diagram of a principle of the data processing module in an embodiment of the present disclosure.

FIG. 15 shows a schematic diagram of a process of first performing sub-pixel adjusting and then performing transition area correction in an embodiment of the present disclosure.

FIG. 16 shows a schematic diagram of a process of first performing transition area correction and then performing sub-pixel adjusting in an embodiment of the present disclosure.

FIG. 17 shows a flow chart of a driving method of a display device in an embodiment of the present disclosure.

FIG. 18 shows a schematic diagram of a structure of a feature boundary area determined according to the light-dark border area FIGB in FIG. 9 in an embodiment of the present disclosure.

FIG. 19 shows a schematic diagram of a structure of a feature boundary area determined according to the light-dark border area FIGA in FIG. 9 in an embodiment of the present disclosure.

FIG. 19-1 shows a schematic diagram of another initial picture in an embodiment of the present disclosure.

FIG. 20 shows a schematic diagram of a structure of a feature boundary area having a first homochromatic contiguous area in an embodiment of the present disclosure.

FIG. 21 is a schematic diagram of a structure in which the transition area includes respective first feature pixels of the feature boundary area when the feature boundary area has a first homochromatic contiguous area, in an embodiment of the present disclosure.

FIG. 22 shows a schematic diagram of a structure in which the transition area includes respective first feature pixels of the feature boundary area and a column of third feature pixels in a first homochromatic contiguous area when the feature boundary area has the first homochromatic contiguous area, in an embodiment of the present disclosure.

FIG. 23 shows a schematic diagram of a structure in which the transition area includes respective first feature pixels of the feature boundary area and two columns of third feature pixels in a first homochromatic contiguous area when the feature boundary area has the first homochromatic contiguous area, in an embodiment of the present disclosure.

FIG. 24 shows a schematic diagram of a structure in which the feature boundary area has a second homochromatic contiguous area in an embodiment of the present disclosure.

FIG. 25 shows a schematic diagram of a structure in which the transition area includes respective second feature pixels of the feature boundary area when the feature boundary area has a second homochromatic contiguous area, in an embodiment of the present disclosure.

FIG. 26 shows a schematic diagram of a structure in which the transition area includes respective second feature pixels of the feature boundary area and a column of fourth feature pixels in a second homochromatic contiguous area when the feature boundary area has the second homochromatic contiguous area, in an embodiment of the present disclosure.

FIG. 27 shows a schematic diagram of a structure in which the transition area includes respective second feature pixels of the feature boundary area and two columns of fourth feature pixels in a second homochromatic contiguous area when the feature boundary area has the second homochromatic contiguous area, in an embodiment of the present disclosure.

FIG. 28 shows a schematic diagram of a structure in which the transition area includes individual pixels of the feature boundary area, a column of third feature pixels in a first homochromatic contiguous area, and a column of fourth feature pixels in a second homochromatic contiguous area, when the feature boundary area has a first homochromatic contiguous area and a second homochromatic contiguous area, in an embodiment of the present disclosure.

FIG. 29 shows a schematic diagram of a process for obtaining a feature boundary area in two adjacent columns of pixels in an embodiment of the present disclosure.

FIG. 30 shows a schematic diagram of a process for obtaining a feature boundary area in two adjacent columns of pixels in an embodiment of the present disclosure.

FIG. 31 is a schematic diagram of a process in which a data processing module outputs to-be-displayed picture data based on the initial picture data in an embodiment of the present disclosure.

FIG. 32 is a schematic diagram of a process in which a data processing module outputs to-be-displayed picture data based on the initial picture data in an embodiment of the present disclosure.

FIG. 33 shows a schematic diagram of a structure of an FPGA board in an embodiment of the present disclosure.

In the accompanying drawings of the specification, the meanings of some of the accompanying symbols used are:
PNL, display panel; CTR, control component; BLU, backlight unit; SubPNL, display sub-panel; Pix, pixel; SP, sub-pixel; SPA, first sub-pixel; SPB, second sub-pixel; SPC, third sub-pixel; BR, border; VSP, column of sub-pixels; DH, row direction; DV, column direction; BA, feature boundary area; PixsA, Feature Pixel Group; Pix1, first feature pixel; Pix2, second feature pixel; Gset, feature gray scale threshold; Pix3, third feature pixel; Pix4, fourth feature pixel; Nset, feature number threshold; TA, Transition Area; MTA, first transition area; TA1, second transition area; TA2, third transition area; CA, homochromatic contiguous area; CA1, first homochromatic contiguous area; CA2, second homochromatic contiguous area; PixsB, first homochromatic pixel group; PixsC, second homochromatic pixel group; DHU, a data handling unit; MU1, a data caching unit; MU2, a transition area determining unit; MUA1, a data comparing unit; MUA2, a data recording accumulation unit; MU3, a transition algorithm unit; MU4, a data output unit; MU5, sub-pixel adjusting unit.

### DETAILED DESCRIPTION

Example embodiments will now be described more fully with reference to the accompanying drawings. However, the example embodiments are capable of being implemented in a variety of forms and should not be construed as being limited to the embodiments set forth herein; rather, the provision of these embodiments allows the present disclosure to be comprehensive and complete and conveys the idea of the example embodiments comprehensively to those skilled in the art. The same reference numbers in the drawings denote the same or similar structures, and thus their detailed descriptions will be omitted. In addition, the accompanying drawings are only schematic illustrations of the present disclosure and are not necessarily drawn to scale.

Although relative terms such as “up” and “down” are used in this specification to describe the relative relationship of one component of an icon to another, these terms are used in this specification only for convenience, such as in accordance with the orientation of the examples described in the accompanying drawings. It will be appreciated that if the device of the icon is flipped so that it is upside down, the component described as being “up” will become the component described as being “down”. When a structure is “on” another structure, it may mean that a structure is integrally formed on the other structure, or that a structure is “directly” set on the other structure, or that a structure is “indirectly” set on the other structure through another structure.

The terms “a”, “the”, “the” and “at least one” are used to indicate the presence of one or more elements/components/etc.; the terms “including” and “having” are used to indicate open-ended inclusion and mean that there may be additional elements/components/etc. in addition to those listed; the terms “first”, “second”, and “third” and the like are used only as markers, and are not intended to be quantitative limitations on the objects thereof.

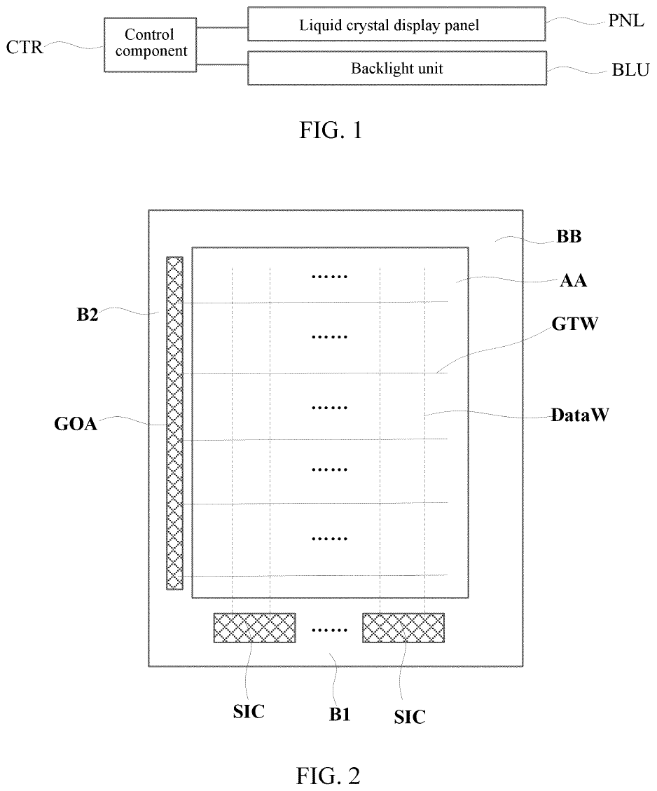

The present disclosure provides a display device that includes a display panel and a control component that drives a display module. FIG. 1 illustrates a schematic diagram of a structure of a liquid crystal display device in one embodiment of the present disclosure. In the example of FIG. 1, the display panel is a liquid crystal display panel, and the display device also has a backlight unit BLU cooperating with the liquid crystal display panel, and the control component CTR drives the liquid crystal display panel and the backlight unit BLU at the same time. In other examples of the present disclosure, the display panel may be other types of display panels as well. For example, it may be an OLED (organic electroluminescent diode) display panel, a Micro LED (micro light emitting diode) display panel, a QD-OLED (quantum dot-organic electroluminescent diode) display panel, a QLED (quantum dot light emitting diode) display panel, a PLED (polymer organic electroluminescent diode) display panel, an LED (light emitting diode) display panel or other active light-emitting display panels.

In the embodiments of the present disclosure, the structure, function, and driving method of the display device of the present disclosure are exemplarily described by taking a liquid crystal display device as an example of the display device.

From the viewpoint of the layered structure, the liquid crystal display panel may include an array substrate and a color film substrate disposed in sequential layers, and a liquid crystal cell surrounded by a border sealant is disposed between the array substrate and the color film substrate, and liquid crystals are disposed in the liquid crystal cell. The liquid crystal display panel further includes a first polarizer located on a side of the array substrate away from the color film substrate and a second polarizer located on a side of the color film substrate away from the array substrate. The array substrate is provided with a pixel electrode and a pixel drive circuit for loading a data voltage to the pixel electrode. The array substrate or the color film substrate is provided with a common electrode. By controlling the electric field strength between the pixel electrode and the common electrode, a degree of twisting or lodging of the liquid crystal within the corresponding range of the pixel electrode can be adjusted, thereby adjusting the direction of polarization of the polarized light that passes through the liquid crystal, and ultimately adjusting the light exit rate of the liquid crystal display panel within the corresponding range of the pixel electrode.

FIG. 2 shows a schematic diagram of a structure of a liquid crystal display panel PNL in the embodiment of the present disclosure. From a planar perspective, the liquid crystal display panel PNL may include a display area AA and a peripheral area BB surrounding the display area AA. In the display area AA, the array substrate is provided with gate lines GTW extending in the row direction and data lines DataW extending in the column direction, and the gate lines GTW and the data lines DataW define a plurality of pixel areas in which the pixel electrodes and pixel driving circuits may be disposed. In the example, the pixel driving circuit may be a thin-film transistor acting as a switching transistor, one end of the switching transistor is electrically connected to the data line DataW, the other end of the switching transistor is connected to the pixel electrode, and the gate of the switching transistor is connected to the gate line GTW. The peripheral area BB of the array substrate has a first peripheral area B1 bound with the source driving circuit SIC, and a second peripheral area B2 having the gate driving circuit GOA provided. The first peripheral area B1 is disposed at one end of the column direction of the array substrate, and the second peripheral area B2 is disposed at one end of the row direction of the array substrate. The gate driving circuit GOA is electrically connected to respective gate lines GTW for loading the gate lines GTW with a scanning signal for turning the switching transistor on. The source driving circuit SIC is electrically connected to the data line DataW for generating a data voltage based on the screen synchronization data and loading the data voltage to the data line DataW.

Referring to FIG. 2, in this example, the number of source driving circuits SICs of the liquid crystal display panel PNL is multiple, and each of the source driving circuits SICs can drive a plurality of the data lines DataW respectively. Further, the source driving circuit SIC is a chip; the array substrate is provided with an FPC (flexible circuit board) binding area and a source driving circuit binding area in the first peripheral area B1. The source driving circuit SIC can be bound within the source driving circuit binding area, and the source driving circuit binding area can be electrically connected to the data line DataW and FPC binding area respectively through wiring. The FPC binding area can be bound with and connected to the control component CTR through FPC. In this way, signals and voltages of the control component CTR can be transmitted to the source driving circuit SIC via the FPC. Further, the signal between the source driving circuit SIC and the control component CTR can be a LVDS (low voltage differential signal) signal or a mini LVDS signal, in order to reduce signal crosstalk.

Of course, in other embodiments of the present disclosure, the liquid crystal display panel PNL can also be presented in other structures. For example, the array substrate can be additionally bound with a gate driving circuit board instead of being provided with a gate drive circuit GOA. For example, the array substrate is provided with a gate drive circuit GOA on both sides in the row direction to reduce the scanning signal voltage drop or to increase the scanning frequency. For example, the array substrate is provided with a source driving circuit

SIC on both sides in the column direction to drive the liquid crystal display panel PNL bilaterally, in order to reduce the voltage drop on the data line DataW in the large-sized liquid crystal display panel PNL, especially to reduce the voltage drop on the data line DataW in the spliced screen. For example, a source driving circuit SIC may be provided not on the liquid crystal display panel PNL, but on a COF (crystal overlay film). The relative positional relationship and the form of setting between the source driving circuit SIC and the display panel PNL are not limited by the present disclosure to the extent that the source driving circuit SIC is capable of directly driving individual pixels in the display area of the PNL.

It will be appreciated that when the display panel is an active light-emitting display panel such as an OLED display panel, a QLED display panel, a Micro LED display panel, or the like, the display panel may include an array substrate provided with a pixel driving circuit and light-emitting elements as sub-pixels without the need to provide a liquid crystal layer or the like. The structure of the sub-pixels of these display panels, as well as the structure of the pixel driving circuit, and the structure of the wiring may be different from those of the liquid crystal display panel, and the present disclosure does not describe this in detail.

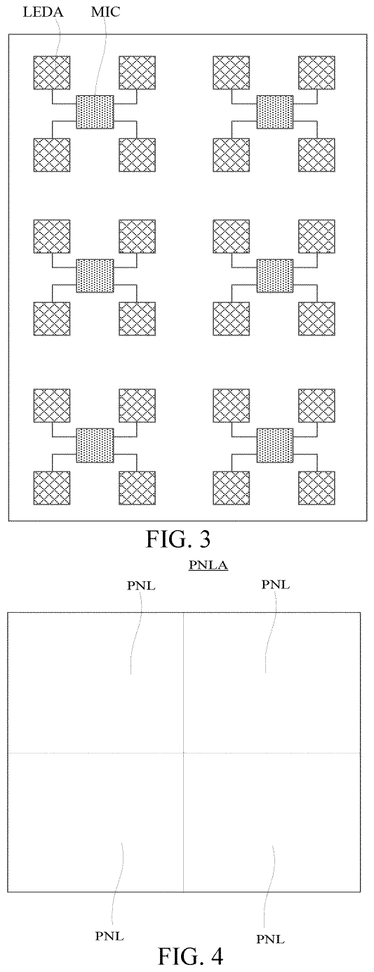

The backlight unit exemplified by the embodiments of the present disclosure is a direct type backlight unit, which includes a light board. FIG. 3 exemplifies a schematic diagram of a structure of a light board of the backlight unit in the embodiment of the present disclosure. Referring to FIG. 3, the light board has light areas LEDA distributed in an array, and there are one or more light emitting elements (e.g., LEDs, such as Mini LEDs or Micro LEDs) that are synchronously controlled within each of the light areas LEDAs. Under the control of the control component CTR, the luminous brightness of the light areas LEDAs can be controlled independently of each other to match the image displayed by the liquid crystal display panel PNL to improve the display effect of the display device. In one example, the control component CTR controls the luminous brightness of the individual light area LEDA by controlling the duty cycles of the individual light-emitting elements when they emit light.

In the example of FIG. 3, the light board may be provided with a microchip MIC, and each microchip MIC may control one or more light areas LEDAs. For example, one microchip MIC controls one light area LEDA or controls four light areas LEDAs. The control component CTR may send the light area data of respective controlled light area to respective microchip MIC. Based on the light area data, the microchip MIC determines the percentage of time (duty cycle) for the electrical conduction and disconnection of respective light area LEDA under its control, thereby controlling the brightness of respective light area LEDA. In other words, the control component CTR can refresh the brightness of respective light area by loading the light area data to respective microchip MIC.

By way of example, in one embodiment, the light board is provided with a control unit, a light area power wiring, a light area ground wiring, a data wiring, etc. Each control unit may include a microchip MIC and light areas LEDA controlled by the microchip MIC. Each light area LEDA includes one light-emitting element or a plurality of light-emitting elements. The plurality of light-emitting elements may be connected in parallel or in series or in a parallel/series mixed connection method. The first power end of the light area LEDA is electrically connected to the light area power wiring, and the second power end of the light area LEDA is electrically connected to the control pin of the microchip MIC. The light area power wiring can be loaded with a more stable driving voltage (ACC), the light area ground wiring can be loaded with ground voltage (GND). When the microchip MIC controls a plurality of light areas LEDA, each light area LEDA is connected to a different control pin. The microchip MIC is connected to the data wiring and the light area ground wiring to receive the light area data from the control component CTR via the data wiring and to control the electrical connection relationship between respective control pin and the light area ground wiring according to the received light area data. Under the control of the microchip MIC, when a control pin is electrically connected to the light area ground wiring, respective light-emitting elements in the light area LEDA connected to the control pin are in a conductive state, and the current on the light area power wiring flows through the light-emitting element to the light area ground wiring, which makes respective light-emitting elements to emit light under a substantially constant current. Under the control of the microchip MIC, when a control pin is electrically disconnected to the light area ground wiring, respective light-emitting elements in the light area LEDA connected to the control pin are in a disconnected state, and the current on the light area power wiring cannot flow through the light-emitting element to the light area ground wiring, which makes respective light-emitting elements do not emit light. In this way, the microchip MIC, under the control of the light area data, can control the duty cycle of respective light-emitting elements in the light area LEDA by controlling the time ratio of the electrical conduction and disconnection of respective control pins, which is reflected in the final effect as the control of the macroscopic brightness of respective light areas LEDA. In this embodiment, the control component CTR is also required to load the microchip MIC with an operating voltage for making the microchip MIC work. The light board may additionally be provided with a chip power line in order to load the operating voltage to the microchip MIC, or the operating voltage may be loaded to the microchip MIC via a data wiring. For example, the data wiring may be multiplexed as a chip power line, which in turn loads both the operating voltage and the light area data to the microchip MIC using power line carrier communication technology.

In one example, the light board may also be provided with a sensor, such as a temperature sensor, a brightness sensor, and the like; sensing signals generated by these sensors may be sent directly to the control component CTR or forwarded to the control component CTR via the microchip MIC, and the control component CTR may adjust the operating state or the operating process of the backlight unit BLU directly based on these sensing signals.

In one example, the light board may include a substrate, a driving layer, and an element layer arranged in sequence. The driving layer is provided with at least two wiring metal layers, such as two wiring metal layers containing copper. The wiring metal layers are separated from each other by an insulating layer, and the insulating layer may be an inorganic insulating layer (e.g., silicon nitride or silicon oxide) or an organic insulating layer (e.g., a resin), or may be stacked inorganic insulating layer and organic insulating layer. The wiring metal layers may be connected to each other by a via hole penetrating through the insulating layers. The surface of the wiring metal layer furthest away from the substrate may be formed with a binding pad for binding electronic component, such as binding light emitting element, microchip MIC, and sensor.

In one example, the substrate of the light board may be a glass substrate. Further, the light board may include a plurality of sub-light boards spliced to each other; the sub-light boards are electrically connected to each other, or the individual sub-light boards are independently and directly controlled by the control component CTR.

In one example, the individual light-emitting elements have the same light-emitting color, for example, they are all blue light-emitting elements. A photoluminescent layer, e.g., a quantum dot film, is also provided on the light board to convert the blue light into a more uniform white light.

In some examples, the backlight unit BLU may also be provided with one or more of a collimation film, a bandpass filter film, a diffusion sheet, a brightness-enhancing sheet, or other optical film materials, without limitation of the present disclosure.

It is understood that the backlight unit BLU of the embodiments of the present disclosure may also adopt other structures, such as adopting a light bar to form a light board, and the present disclosure does not introduce each of these ways.

In some embodiments of the present disclosure, by referring to FIG. 4, a plurality of display panels PNL may be spliced into a larger-sized spliced panel PNLA using the display panels PNL as the spliced unit. In this way, the shape of the spliced panel PNLA may be adjusted or the size of the spliced panel PNLA may be increased. In one example, the display panel PNL may be a large-sized display panel PNL. For example, it may be a display panel no less than 45 inches, in particular, a 55-inch display panel. In another embodiment, the display panel PNL may be a special-shaped panel, e.g., may have a plurality of different projections.

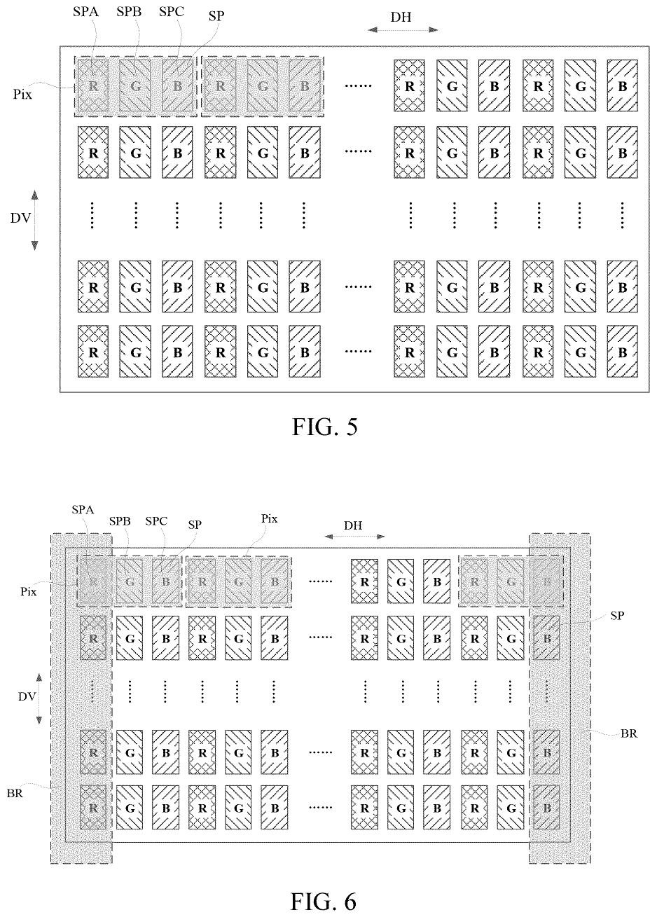

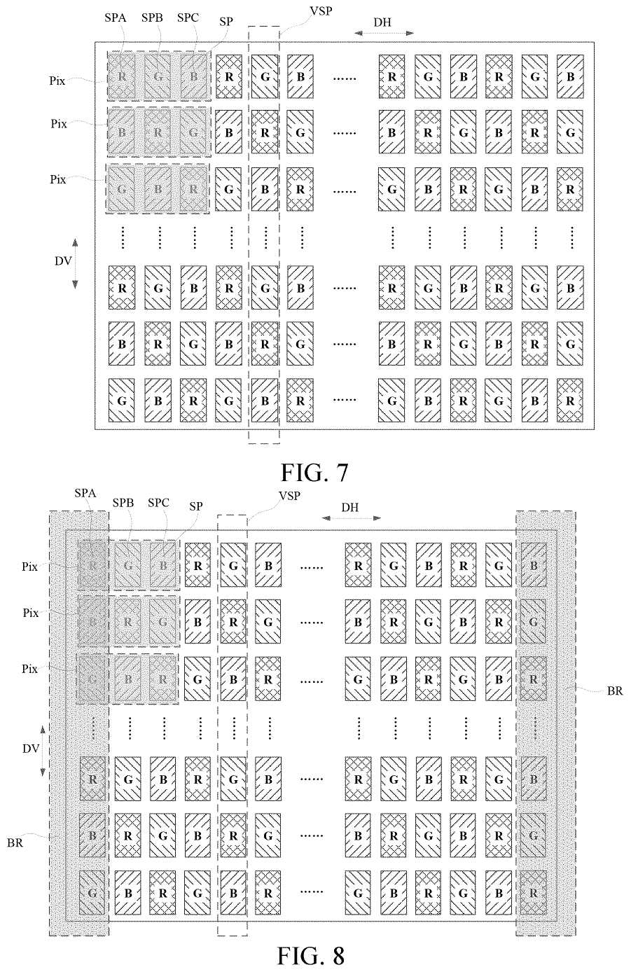

Referring to FIGS. 6 and 7, the display panel PNL in the embodiment of the present disclosure includes pixels Pix distributed in an array. Any one of the pixels Pix includes a plurality of sub-pixels SP sequentially adjacent along the row direction DH, and in particular, includes a plurality of sub-pixels SP that are capable of emitting lights of different colors. In the example of FIGS. 6 and 7, the pixel Pix includes three different sub-pixels SP with different light-emitting colors, which are a first sub-pixel SPA, a second sub-pixel SPB, and a third sub-pixel SPC. For example, the first sub-pixel SPA may emit red light as a red sub-pixel R, the second sub-pixel SPB may emit green light as a green sub-pixel G, and the third sub-pixel SPC may emit blue light as a blue sub-pixel B. In other examples of the present disclosure, the Pixel Pix may include sub-pixel SPs of other colors or other numbers of sub-pixel SPs.

Referring to FIGS. 6 and 7, the display panel PNL includes a plurality of pixel columns, and any one of the pixel columns includes a plurality of pixels sequentially arranged along the column direction DV. The pixel column includes a plurality of sub-pixel columns VSP, and each sub-pixel column VSP includes a plurality of sub-pixels SP sequentially arranged along the column direction DV.

In one embodiment of the present disclosure, the display panel PNL of the present disclosure may have a narrow border with a small distance between an edge of the display area AA of the display panel PNL and an edge of the display panel PNL on its corresponding side. For example, on at least one side of the display panel PNL, the distance between the edge of the display area AA of the display panel PNL and the edge of the display panel PNL on this side is not greater than 2 millimeters; for example, the distance between a sub-pixel of the edge of the display panel PNL and the edge of the display panel PNL is in the range of 1.4 to 1.5 millimeters. For example, on at least one side of the display panel PNL, the distance between the edge of the display area AA of the display panel PNL and the edge of the display panel PNL on this side is not greater than 1 millimeter; for example, the distance between the sub-pixels of the edge of the display panel PNL and the edge of the display panel PNL is between 0.58 mm to 0.68 mm. Specifically, the at least one side of the display panel PNL includes a side where the display panel PNL is spliced with another display panel, so that the width of the area not displayed at the location where the display panel PNL is spliced with another display panel is narrower and the display effect is better.

For example, on each side of the display panel PNL, a distance between an edge of the display area AA of the display panel PNL and an edge of the display panel PNL on this side is not greater than 2 mm; for example, a distance between a sub-pixel of an edge of the display panel PNL and an edge of the display panel PNL is 1.7 mm. For example, on each side of the display panel PNL, a distance between an edge of the display area AA of the display panel PNL and an edge of the display panel PNL on this side is no greater than 1 mm; for example, the distance between the sub-pixels of the edge of the display panel PNL and the edge of the display panel PNL is 0.88 mm.

For example, the edge contour of the display panel PNL is rectangular, the the edge contour of the display area AA is rectangular, and the overall edge contour of the spliced panel PNLA is rectangular.

When the display panel PNL with a narrow border is applied to a display device, there is a risk that the sub-pixels SP near the edge are obscured by the border BR of the display device due to the height and viewing angle of the border BR of the display device. By way of example, referring to FIG. 8, in one example of the present disclosure, the distance between the sub-pixel columns VSP closest to the edge of the display area AA and the border of the display device is small, and since the border BR has a certain height, the border BR may block the light emitted from the sub-pixel columns VSP when viewed by a user from a large viewing angle, which may result in the sub-pixel columns VSP being visually occluded by the border BR. It will be appreciated that, in practice, the display panel PNL will generally be placed perpendicular to the horizontal plane, and at this time, the borders BR on the left and right sides of the display panel PNL (with reference to the opposite sides along the direction of the rows of pixels Pix in FIG. 8) are prone to obscure the sub-pixel columns VSPs when viewed by the user from a large viewing angle.

FIGS. 5 and 6 illustrate how the sub-pixels SP in pixel Pix are arranged in the related art. Referring to the examples of FIGS. 5 and 6, in the related art, the sub-pixels SP in the individual pixel Pix are arranged in the same manner, which results in the same color of the same column of sub-pixels SP. For example, in the related art, the sub-pixel arrangement of the pixel Pix may be a Real RGB structure. However, when the display panel PNL in the related art is applied to a display device with a narrow border, the sub-pixel columns VSP at the edges of the display panel PNL may be obscured by the border BR of the display device at a large viewing angle. In this case, the displayed image is prone to color deviation, such as reddish or cyanish, at a position near the edge (edge in the row direction).

In order to overcome this defect, and ensure the good display effect for the display device of the present disclosure with a narrow border, referring to FIGS. 7 and 8, in an embodiment of the present disclosure, individual sub-pixels SP may be arranged into a plurality of sub-pixel columns VSPs, and the individual sub-pixel columns VSPs are arranged sequentially along the row direction DH and extend along the column direction DV; each sub-pixel column VSP includes a plurality of sub-pixels SPs provided in the same column. Referring to the examples of FIGS. 7 and 8, two adjacent sub-pixels SP in the same sub-pixel column VSP have different colors. In this way, in the embodiment of the present disclosure, the sub-pixels of the display panel PNL are interleaved, i.e., the sub-pixels SP of two adjacent pixels Pix along the column direction DV are arranged in a different way. Referring to FIG. 8, even if the sub-pixel column VSP of the display panel PNL of the present disclosure close to the border BR of the display device is obscured at a large viewing angle, the remaining sub-pixel columns VSP are not single-colored sub-pixel columns VSP, but are sub-pixel columns VSP having a plurality of differently colored sub-pixels. In this way, display anomalies appearing at the edges of the displayed image can be avoided or effectively reduced.

Further, the pixels Pix set in the same row have the same sub-pixel SP arrangement.

In one example, referring to FIG. 7, the sub-pixels SP of the pixel Pix are arranged in a periodic manner according to a cycle of every three rows. In each cycle, sub-pixels SPs of a row of pixels Pix are arranged in such a way that a first sub-pixel SPA, a second sub-pixel SPB, and a third sub-pixel SPC are sequentially arranged along the row direction DH; sub-pixels SPs of a row of pixels Pix are arranged in such a way that a second sub-pixel SPB, a third sub-pixel SPC, and a first sub-pixel SPA are sequentially arranged along the row direction DH; and sub-pixels SPs of a row of pixels Pix are arranged in such a way that a third sub-pixel SPC, a first sub-pixel SPA and a second sub-pixel SPB are sequentially arranged along the row direction DH.

In one example of the embodiments of the present disclosure, the spliced panel PLNA includes a plurality of display panels PNLs spliced with each other, and the individual display panels PNLs may be used as spliced units of the spliced panel. In order to reduce the width of the spliced lines between the display panels PNLs, the size of the borders of the display panels PNLs may be reduced, i.e., display panels PNLs are made to have an extremely narrow border. This allows sub-pixels of the display panel PNL to be close to the edge of the display panel PNL. On the spliced panel PLNA, the sub-pixels of the spliced panel PLNA are also close to the edges of the spliced panel PLNA, making the sub-pixels SP close to the edges of the spliced panel PLNA easily being obscured by the border BR of the display device at a large viewing angle. In the embodiments of the present disclosure, by interleaving the individual sub-pixels, a cyanish edge or a reddish edge caused by the sub-pixel columns VSP being obscured by the border BR can be avoided. Specifically, the sub-pixel column VSP obscured by the border BR includes sub-pixels SP of respective colors, which does not lead to macroscopic color deviation of pixels Pix close to the border BR due to sub-pixels SP of the same color being obscured at a large viewing angle.

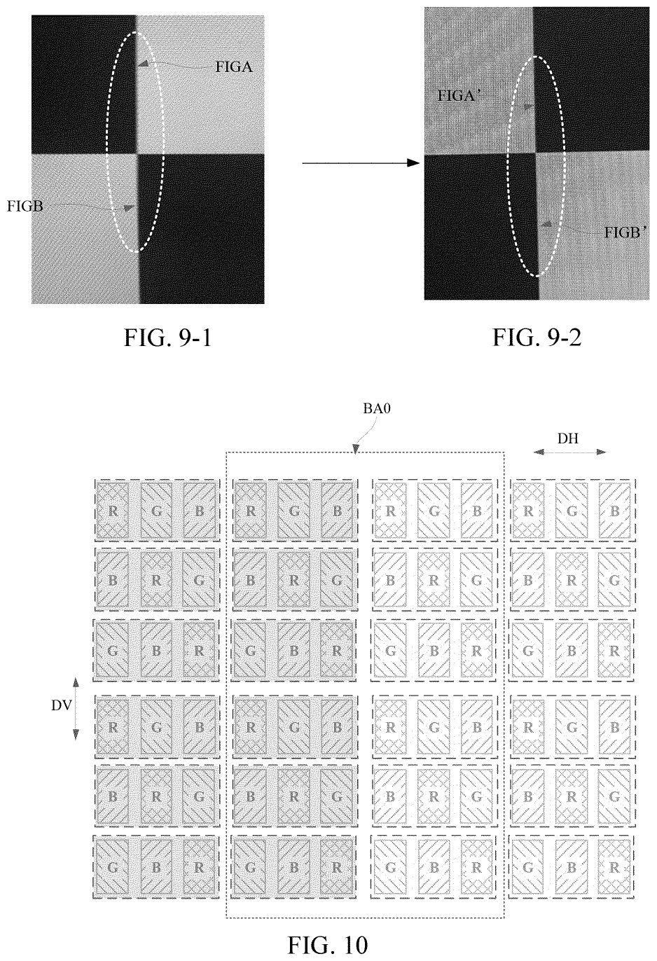

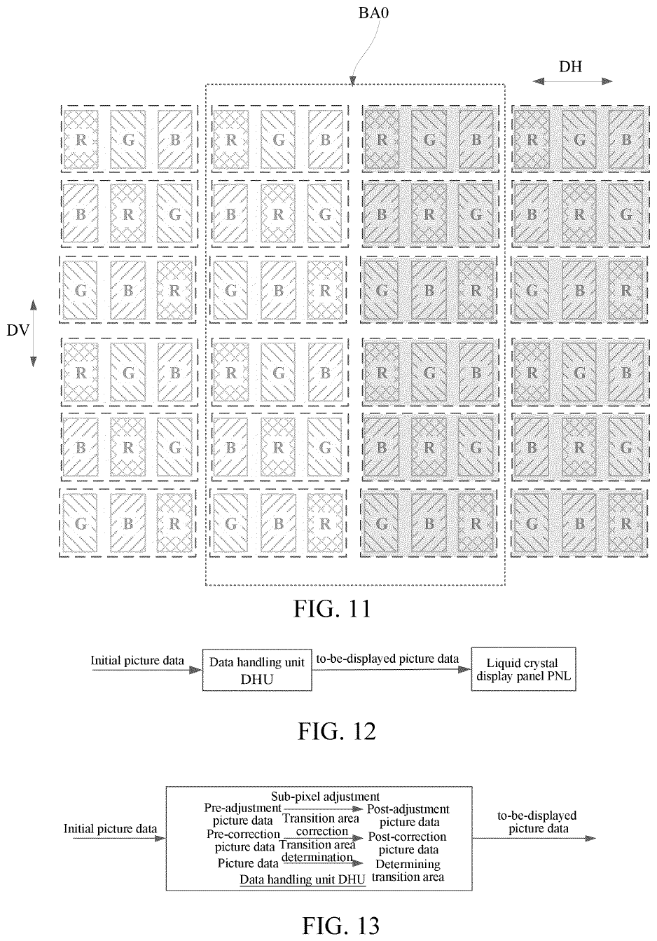

Under normal circumstances, because the sub-pixels SP of two adjacent pixels Pix in each pixel column are arranged differently, each pixel column will exhibit a certain jagged effect when displaying some images; this jagged effect is basically invisible under the influence of the mixing of light of the surrounding pixels and the like, and will not affect the display effect. However, when a conventional driving method is used to drive the display device of the embodiment of the present disclosure, by referring to FIG. 9-1, when the display panel PNL displays a picture having a light-dark boundary, light-dark demarcation vertical line (a line in the column direction) may exhibit visible jaggedness; for example, in the case of a large difference in brightness and darkness between the two sides of light-dark demarcation vertical line, and when light-dark demarcation vertical line reaches a certain length, light-dark demarcation vertical line displayed on the display panel PNL exhibits visible jaggedness. For example, on both sides of the light-dark demarcation area (circled with dotted lines) of FIG. 9-1, a light pattern with higher brightness is on one side and a dark pattern with lower brightness is on the other side; light-dark demarcation vertical line FIGA (a line in the column direction) and light-dark demarcation vertical line FIGB in the light-dark demarcation area may exhibit visible jaggedness. FIG. 10 illustrates a locally enlarged schematic diagram near the light-dark demarcation vertical line FIGA, and FIG. 11 illustrates a locally enlarged schematic diagram near the light-dark demarcation vertical line FIGB. According to FIG. 10 and FIG. 11, it can be seen that there is a demarcation area BAO including two columns of pixels in the light-dark demarcation area, and one column of pixels in the demarcation area BAO has a higher brightness and the other column of pixels has a lower brightness. Due to the perception of the human eyes, the boundary position of the two columns of pixels in the demarcation area BAO exhibits jaggedness which is macroscopically visible, thereby influencing the display effect.

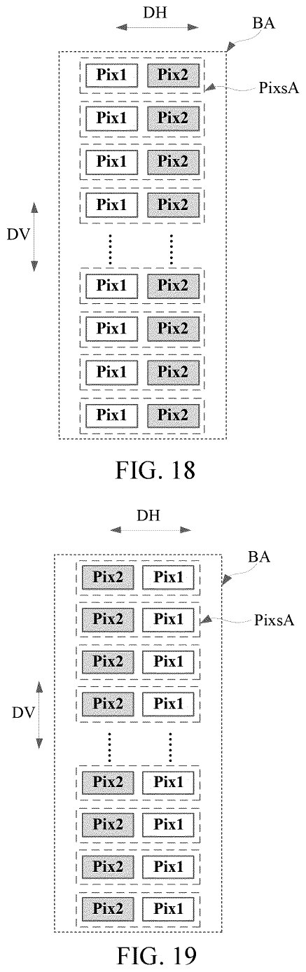

The display device, provided by Embodiments of the present disclosure, can display a target picture based on received picture data of an initial picture. Referring to FIG. 18, there is at least one feature boundary area BA in the initial picture, and the feature boundary area BA includes a plurality of feature pixel groups PixsA sequentially adjacent along a column direction DV. The feature pixel groups PixsA includes a first feature pixel Pix1 and a second feature pixel Pix2, which are adjacent in a same row, and the difference between the brightness of the first feature pixel Pix1 and the brightness of the second feature pixel Pix2 is greater than or equal to a brightness threshold Lset. In FIGS. 18 to 28, sub-pixels filled with lighter colors denote sub-pixels with higher brightness (accordingly, with a larger gray scale); sub-pixels filled with darker colors denote sub-pixels with lower brightness (accordingly, a less gray scale). Respective first feature pixels Pix1 in the same feature boundary area BA is provided in the same column. For the same area as the feature boundary area BA of the initial picture, the difference between the brightness of the first feature pixel Pix1 and the brightness of the second feature pixel Pix2 in the target picture is less than the difference in the initial picture. In this way, the display device of the present disclosure can correct the gray scale of at least some of the pixels within the feature boundary area BA in the initial picture before displaying it, so that the actually displayed target picture has a transition area TA extending along the column direction DV between at least some of the light pattern and the dark pattern. The light pattern, the transition area TA and the dark pattern are arranged along the row direction DH. The transition area TA can realize the brightness transition between the light pattern and the dark pattern (which is reflected in the picture data level as realizing the gray scale transition), which can avoid the visible jaggedness of the light-dark demarcation vertical line due to the large difference in brightness between two adjacent columns of pixels. Of course, it is understood that in some cases, for example, in a case where there is no feature boundary area BA in the initial picture, or in a case where there is no need to correct the grayscales of the feature boundary area BA and the pixels around the feature boundary area BA, the initial picture may be the same as the target picture. It is to be understood that when the initial picture is different from the target picture, the grayscales of at least some of the pixels in the feature boundary area BA of the initial picture are corrected. The grayscales of the pixels adjacent to the feature boundary area BA may also be corrected in some cases (i.e., the transition area TA may extend beyond the feature boundary area BA) to make the transition of brightness between the light pattern and the dark pattern smoother.

In other words, the display device of the present disclosure is capable of displaying a target picture based on the received picture data of the initial picture. The display device is configured to: generate a target picture by adjusting the brightness of at least some pixels of the feature boundary area when the initial picture includes at least one feature boundary area. The feature boundary area includes a plurality of groups of feature pixels sequentially adjacent in a column direction. The group of feature pixels includes a first feature pixel and a second feature pixel, the first feature pixel and the second feature pixel are adjacent to each other in the same row, and a brightness difference between the first feature pixel and the second feature pixel is greater than or equal to a brightness threshold. The respective first feature pixels in the same feature boundary area are provided in the same column. For a position corresponding one-to-one to a pixel in the feature boundary area of the initial picture, the difference between the brightness of the first feature pixel and the brightness of the second feature pixel in the target picture is less than the difference between the brightness of the first feature pixel and the brightness of the second feature pixel in the initial picture.

The embodiment of the present disclosure also improves the control component CTR of the display device and the driving method of the display device to realize displaying a target picture with a good display effect based on the picture data of the initial picture, such that a brightness transition in the row direction exhibits between at least some of the light pattern and the dark pattern in the target picture, thereby making the jaggedness of the light-dark demarcation vertical lines invisible or reducing the degree of visibility thereof.

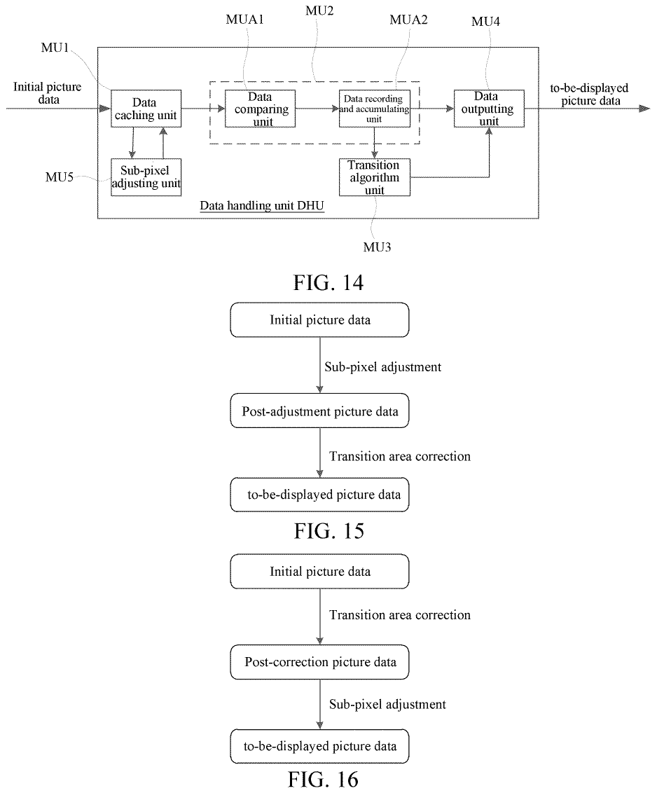

In embodiments of the present disclosure, the control component CTR may include a data processing module for processing picture data. FIG. 12 illustrates an overall processing result of the picture data by the data handling unit DHU in an embodiment of the present disclosure, and FIG. 13 illustrates some processing of the data by the data handling unit DHU in an embodiment.

Referring to FIG. 12, in general, the data handling unit DHU may receive initial picture data (i.e., picture data of an initial picture), then process the initial picture data to obtain to-be-displayed picture data, and then drive a display panel PNL to display based on the to-be-displayed picture data, and the picture displayed by the display panel PNL is a target picture. In the example of FIG. 12, the data handling unit DHU may obtain the to-be-displayed picture data and send the to-be-displayed picture data to the display panel PNL (e.g., to a source driving circuit of the display panel PNL); the display panel PNL displays a picture based on the to-be-displayed picture data. In the present disclosure, the initial picture data refers to the picture data received by the control component CTR through a signal port, such as video data received through an HDMI port or a DP port, etc. The to-be-displayed picture data refers to picture data that can be directly utilized by the display panel PNL to display a picture, i.e., picture data sent to the display panel PNL (i.e., synchronized picture data).

In some embodiments, the initial picture data is provided in the same manner as the arrangement of the sub-pixels SP of each pixel Pix. In terms of layout, the sub-pixels SP of at least some of the pixels Pix in this initial picture data are out of order with the sub-pixels of at least some of the pixels Pix in the display panel PNL.

In one case, the order of the data of the sub-pixels in the picture data may be adjusted in accordance with a predetermined sub-pixel adjusting algorithm so that the arrangement order of the data of the sub-pixels in the picture data to be displayed is the same as the arrangement order of the sub-pixels on the display panel.

In other cases, the data loading order of the sub-pixels has already been adjusted on the display panel PNL by hardware means, and thus there is no need to adjust the order of the sub-pixels in the picture data. In one example, the display panel PNL is provided with a source driving chip; the source driving chip is preset with an adjusting algorithm or is provided with an adjusting circuit; the control component CTR may load the picture data to be displayed to the source driving chip of the display panel in accordance with a RealRGB format, and the source driving chip may, in accordance with the preset adjusting algorithm or the adjusting circuit, adjust the picture data to be displayed and drive the individual sub-pixels. In another example, the data lines used to drive the sub-pixels in the display panel are arranged according to a preset arrangement, and the order of loading the data voltages of the sub-pixels can be changed, so that the data voltages of the sub-pixels can be loaded to the individual sub-pixels; in other words, the order of driving the sub-pixels can be adjusted through the arrangement setting of the data lines.

Of course, in other embodiments of the present disclosure, the order of the sub-pixels of the initial picture data is the same as the arrangement order of the sub-pixels of the display panel, and there is no need to adjust the order of the picture data by means of an algorithm or hardware.

In one embodiment of the present disclosure, the picture data needs to be adjusted in the data handling unit DHU by means of a sub-pixel adjusting algorithm or a sub-pixel adjusting circuit. Referring to FIG. 13, the processing of the initial picture data by the data handling unit DHU includes at least three processes, i.e., a sub-pixel adjusting process, a transition area determining process, and a transition area correcting process.

Specifically, the sub-pixel adjusting process is configured to perform sub-pixel adjusting on the pre-adjustment picture data to obtain the post-adjustment picture data; the arrangement of the sub-pixels SP of the pixels Pix of the adjusted picture data is same as the arrangement of the sub-pixels SP of the pixels Pix of the display panel PNL. It is understood that the sub-pixel adjusting process in the data handling unit DHU is not necessary, as in the above example, the sub-pixel adjusting process may be performed in other hardware, or the order of the sub-pixels of the initial picture data is same as the arrangement order of the sub-pixels of the display panel.

The transition area determining process is configured to determine, based on the picture data, which columns of pixels serve as a transition area TA for a gray scale transition between a light pattern and a dark pattern. The transition area correcting process is configured to perform transition area correction (i.e., correct the gray scale of pixels in the transition area TA) on the pre-correction picture data to obtain the post-correction picture data; the post-correction picture data is capable of having a brightness transition along the row direction DH between at least a part of the light pattern and the dark pattern; i.e., there exists a transition area TA extending along the column direction DV between the light pattern and the dark pattern, and the transition area TA is used for the brightness transition between the adjacent light pattern and the dark pattern (in terms of the corrected picture data, it can be reflected as a gray scale transition of the pixels, and in terms of the final display effect, it can be reflect as a brightness transition). The sequence of the sub-pixel adjusting process and the transition area correcting process is not specifically limited. In the present disclosure, the pre-adjustment picture data and the post-adjustment picture data are the names of different picture data in the sub-pixel adjusting process; the pre-correction picture data and the post-correction picture data are the names of different picture data in the transition area correcting process; and the initial picture data and the picture data to be displayed are data received and outputted by the data handling unit DHU. The same picture data can be called by different names in different processes. The sequence of the transition area determining process and the sub-pixel adjusting process is not specially defined; the sub-pixel adjusting process does not change the gray scale of the pixels, and therefore does not lead to a change in the result of the transition area determining process. When processing the same frame of the initial picture data, the transition area determining process needs to precede the transition area correcting process, and the transition area correcting process corrects the gray scale of the pixel based on the transition area TA determined by the transition area determining process.

In one example, referring to FIG. 15, a sub-pixel adjusting process may be performed first, followed by a transition area correcting process. In this example, the initial picture data may be used as the pre-adjustment picture data, and the picture data after the sub-pixel adjusting is the post-adjustment picture data, and the post-adjustment picture data is also simultaneously used as the pre-correction picture data. The pre-correction picture data is corrected by the transition area to obtain the post-correction picture data, and the post-correction picture data is used as the picture data to be displayed.

In another example, referring to FIG. 16, a transition area correction process may be performed first, followed by a sub-pixel adjusting process. In this example, the initial picture data may be used as the pre-correction picture data; the pre-correction picture data is corrected by the transition area to obtain the post-correction picture data. The post-correction picture data also serves as the pre-adjustment picture data; the pre-adjustment picture data is subjected to the sub-pixel adjusting process to obtain the post-adjustment picture data; and the post-adjustment picture data serves as the picture data to be displayed.

In an embodiment of the present disclosure, the sub-pixel adjusting process is configured to perform sub-pixel adjusting on the pre-adjustment picture data to obtain the post-adjustment picture data. In the pre-adjustment picture data, the gray scales of the sub-pixels SP of individual pixels are arranged in accordance with the same arrangement of the sub-pixels SP of the individual pixels. In the post-adjustment picture data, the gray scales of the sub-pixels SP of the individual pixels Pix are arranged in accordance with the arrangement of the sub-pixels SP of the individual pixels of the display panel PNL of the embodiment of the present disclosure.

For example, in the pre-adjustment picture data, data of any pixel includes the gray scales of three sub-pixels arranged in sequence, i.e., the gray scale GR of the red sub-pixel, the gray scale GG of the green sub-pixel, and the gray scale GB of the blue sub-pixel, arranged in sequence. In such arrangement, the red, green, and blue sub-pixels of each pixel are arranged in the same order by default, i.e., keep the red sub-pixel R, the green sub-pixel G, blue sub-pixel B arranged in sequence. However, in the display panel PNL of the present disclosure, the arrangements of the sub-pixels SP of different pixels Pix may be different, and the pre-adjustment picture data is not directly applicable to the driving of the display panel PNL of the present disclosure. For example, when the individual sub-pixels SP of one pixel Pix of the present disclosure are arranged sequentially in the order of the blue sub-pixel B, the red sub-pixel R, and the green sub-pixel G, it is necessary to adjust the arrangement order of the grayscales of the individual sub-pixels SP according to the actual arrangement of the sub-pixels SP, so that the data of the pixel Pix after the adjustment includes the grayscale GB of the blue sub-pixel, the grayscale GR of the red sub-pixel and the gray scale GG of the green sub-pixel in sequence.

In one example, referring to FIG. 7, each pixel Pix in a display panel PNL of an embodiment of the present disclosure includes a first sub-pixel SPA, a second sub-pixel SPB, and a third sub-pixel SPC; and the sub-pixel SPs of the pixel Pix are arranged in a periodic manner according to a cycle of every three rows. In each cycle, the sub-pixels SPs of the first row of pixels Pix are arranged in such a way that the first sub-pixel SPA, the second sub-pixel SPB, and the third sub-pixel SPC are sequentially arranged along the row direction DH; the sub-pixels SPs of the second row of pixels Pix are arranged in such a way that the second sub-pixel SPB, the third sub-pixel SPC, and the first sub-pixel SPA are sequentially arranged along the row direction DH; and the sub-pixels SPs of the third row of pixels Pix are arranged in such a way that the third sub-pixel SPC, the first sub-pixel SPA, and the second sub-pixel SPB are sequentially arranged along the row direction DH. Each pixel Pix data in the pre-adjustment picture data includes a gray scale of the first sub-pixel SPA, a gray scale of the second sub-pixel SPB, and a gray scale of the third sub-pixel SPC in sequence. The data handling unit DHU adjusts the order of the gray scales of the sub-pixels SPs in individual pixel data in the pre-adjustment picture data by the sub-pixel adjusting algorithm or the sub-pixel adjusting unit. Since the interleaving is arranged in a cycle of 3 rows, the arrangement order of the gray scales of the sub-pixels SP in the pixel data of the first row of pixels remains unchanged; the arrangement order of the gray scales of the sub-pixels SP in the pixel data of the second row of pixels is adjusted to the gray scale of the second sub-pixel SPB, the gray scale of the third sub-pixel SPC, and the gray scale of the first sub-pixel SPA; and the arrangement order of the gray scales of the sub-pixels SP in the pixel data of the third row of pixels is adjusted to the gray scale of the third sub-pixel SPC, the gray scale of the first sub-pixel SPA and the gray scale of the second sub-pixel SPB. The data of the subsequent rows of pixels are cyclically adjusted in the order of these 3 rows. The sub-pixel adjusting process only changes the order of the gray scales of the sub-pixels within the pixel data, and thus is only an order adjustment of the gray scales of the sub-pixels within the pixel data; the sub-pixel adjusting algorithm or the sub-pixel adjusting unit only needs to sequentially adjust the order of the gray scales of the sub-pixels within each of the pixel data and set up a cycle of 3 rows.

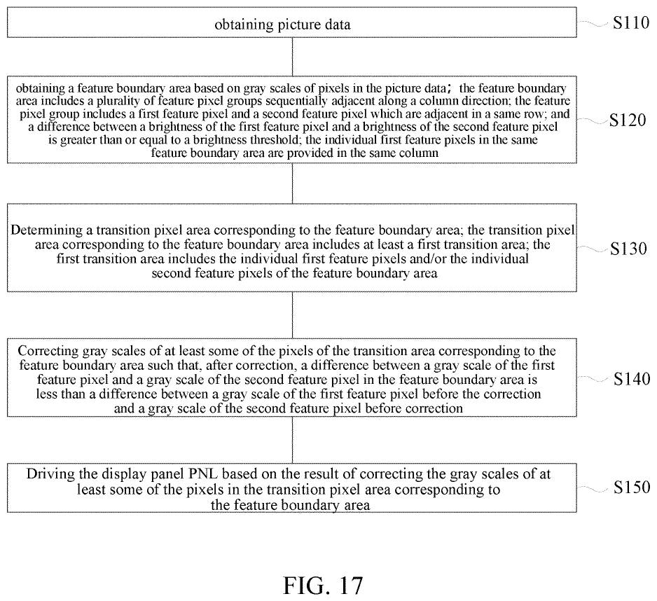

In embodiments of the present disclosure, a transition area determining process and a transition area correcting process need to be performed sequentially to obtain the post-correction picture data. In some embodiments of the present disclosure, referring to FIG. 17, the driving method of the display device may include the steps shown in steps S110 to steps S150. Steps S120 and S130 relate to the transition area determining process, and step S140 relates to the transition area correcting process.

Step S110, obtaining picture data. The picture data is pre-correction picture data, which may be either initial picture data or post-adjustment picture data.

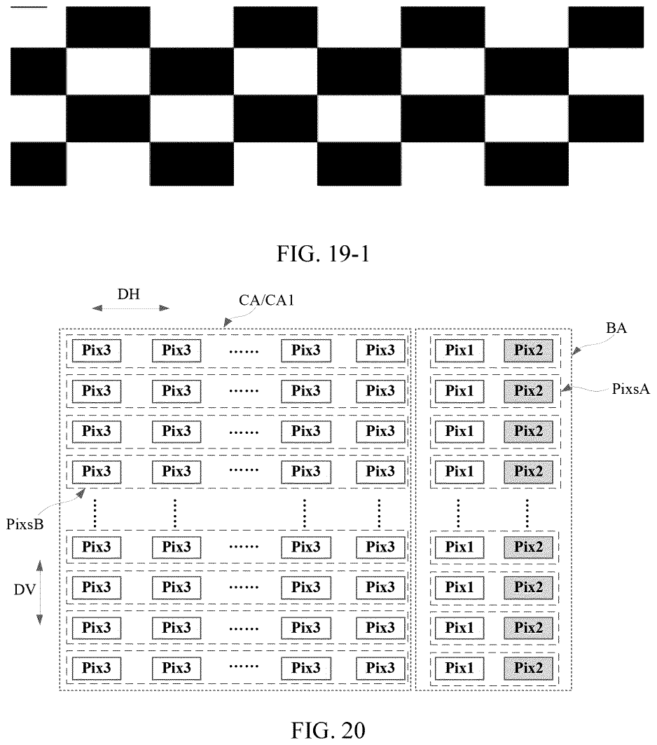

Step S120, referring to FIGS. 18 and 19, obtaining a feature boundary area BA based on gray scales of pixels Pix in the picture data. The feature boundary area BA includes a plurality of feature pixel groups PixsA sequentially adjacent along a column direction DV. The feature pixel group PixsA includes a first feature pixel Pix1 and a second feature pixel Pix2 which are adjacent in a same row; and a difference between a brightness of the first feature pixel Pix1 and a brightness of the second feature pixel Pix2 is greater than or equal to a brightness threshold Lset. The individual first feature pixels Pix1 in the same feature boundary area BA are provided in the same column, and the first feature pixel Pix1 is located on the same side of the second feature pixel Pix2 in the same feature boundary area BA. In the embodiment of the present disclosure, the first feature pixel Pix1 and the second feature pixel Pix2 are classified according to the size of the gray scale (or brightness) of the pixels in the feature pixel group PixsA. Referring to FIGS. 18 and 19, the relative positions of the first feature pixel Pix1 and the second feature pixel Pix2 may be different in different feature boundary areas BA; of course, they may be same in other examples.

Step S130, referring to FIGS. 20 to 28, determining a transition area TA corresponding to the feature boundary area BA. The transition area TA corresponding to the feature boundary area BA includes at least a first transition area MTA. The first transition area MTA includes the individual first feature pixels Pix1 and/or the individual second feature pixels Pix2 of the feature boundary area BA. For example, the transition area TA is continuously distributed in the row direction. For example, in the row direction, the first transition area MTA only includes pixel at the column in which the first feature pixel Pix1 is located.

Step S140, correcting gray scales of at least part of the pixels Pix of the transition area TA corresponding to the feature boundary area BA such that a difference between a brightness of the first feature pixel Pix1 and a brightness of the second feature pixel Pix2 in the feature boundary area BA is less than a difference between a brightness of the first feature pixel Pix1 before the correction and a brightness of the second feature pixel Pix2 before correction. In this way, the difference in brightness between the two columns of pixels at the feature boundary area BA can be attenuated, and a visible degree of jaggedness of the edges of the columns of pixels can be attenuated.

Step S150, driving the display panel PNL based on the result of correcting the gray scales of at least part of the pixels Pix in the transition area TA corresponding to the feature boundary area BA. The result of correcting the gray scales of at least part of the pixels Pix in the transition area TA corresponding to the feature boundary area BA may be used as part of the post-correction picture data for driving the display panel PNL. In some embodiments, the pre-correction picture data has not been subjected to sub-pixel adjusting, and this post-correction picture data needs to be subjected to sub-pixel adjusting first to form the corrected post-adjustment picture data, and the corrected post-adjustment picture data is used to drive the display panel PNL. In some embodiments, the pre-correction picture data has been subjected to sub-pixel adjusting, and this post-correction picture data is the post-adjustment corrected picture data, and this post-adjustment corrected picture data is used to drive the display panel PNL. In some embodiments, there is no need for the picture data to subject to sub-pixel adjusting, and it's not necessary to perform the sub-pixel adjusting.

In the steps of the driving method described above, the sub-pixel adjusting process is not described. However, in some embodiments of the present disclosure, the driving method of the present disclosure may include a sub-pixel adjusting step, which may be before the transition area correcting process (step S140) or after the transition area correcting process (step S140). Of course, if there is no need for the picture data to subject to sub-pixel adjusting, the driving method does not include the sub-pixel adjusting step.

As follows, various steps of the disclosed driving method are exemplarily described in connection with the accompanying drawings.

Referring to FIGS. 18 and 19, the feature boundary area BA of the present disclosure is determined based on the picture data before the transition area correcting, and the feature boundary area BA includes a plurality of feature pixel groups PixsA sequentially adjacent along the column direction DV. Any one of the feature pixel groups PixsA may include only two pixels Pix, i.e., a first feature pixel Pix1 having a higher gray scale and a second feature pixel Pix2 having a lower gray scale; in other words, the brightness of the first feature pixel Pix1 is greater than the brightness of the second feature pixel Pix2. The difference in brightness between the first feature pixel Pix1 and the second feature pixel Pix2 is greater than or equal to a brightness threshold Lset. The individual first feature pixels Pix1 are located in the same pixel column and the individual second feature pixels Pix2 are located in the same pixel column. In this way, there is a light-dark demarcation vertical line between the light pattern and the dark pattern in the initial picture between the first feature pixel Pix1 and the second feature pixel Pix2; and a difference in brightness between the light pattern and the dark pattern is greater than or equal to the brightness threshold Lset.

Further, the number of feature pixel groups PixsA included in the feature boundary area BA is not less than the feature number threshold Nset. That is, the light-dark demarcation vertical line needs to have a certain length before it may present obvious jaggedness. In one example, the feature number threshold Nset is a positive integer not less than 5. For example, the feature number threshold Nset is equal to one of 5, 6, 7, 8, 9, 10. Of course, the feature number threshold Nset is not greater than the total number of pixel rows of the display panel PNL. When the number of feature pixel groups PixsA sequentially arranged along the column direction is less than the feature number threshold, these feature pixel groups PixsA are not capable of forming the feature boundary area BA, and the control component does not process these feature pixel groups PixsA in accordance with the feature boundary area BA. For example, the feature number threshold Nset is equal to 5, and when the number of feature pixel groups PixsA sequentially arranged along the column direction is less than 5, for example, 1 to 4, the control component does not process the 1 to 4 feature pixel groups PixsA as a feature boundary area BA. When the number of feature pixel groups PixsA sequentially arranged along the column direction is not less than 5, the control component will process these feature pixel groups PixsA as one feature boundary area BA.

In this case, the brightness difference between the two sides of the light-dark demarcation vertical line is greater than or equal to a brightness threshold Lset, for example greater than 50 nits, and the light-dark demarcation vertical line has a certain length. If the gray scales of the pixels on both sides of the light-dark demarcation vertical line are not corrected, the light-dark demarcation vertical line in the target picture is likely to have visible jaggedness, which affects the display effect. In the driving method of the embodiment of the present disclosure, respective feature boundary areas BA can be found out based on the pre-correction picture data, and then the transition area correction can be performed on the pre-correction picture data based on the respective feature boundary areas BA.

The inventor found that when the brightness threshold Lset is set to 50 nits and the light-dark demarcation vertical line has a certain length (the feature number threshold is 5), the jaggedness of the light-dark demarcation vertical line can be improved and the display effect can be enhanced by making too much adjustment to the target picture. It should be noted that, according to the actual needs, the brightness threshold Lset can also be set to other values, such as a value between 40-60 nits, or other values greater than 50 nits, as long as the jaggedness can be effectively eliminated.

It is to be understood that the driving method of the embodiment of the present disclosure may perform transition area determination and transition area correction for each frame of picture data. In this way, different feature boundary areas BA can be obtained for different picture data; of course, it is also possible that some or all of the feature boundary areas BA remain unchanged. In addition, even though the same feature boundary area BA may be determined for two initial pictures, the first feature pixel Pix1 and the second feature pixel Pix2 in the feature boundary area BA may be changed; of course, it is also possible that they may be unchanged. In other words, the driving method of the embodiment of the present disclosure can obtain the feature boundary area BA independently for each frame of the picture data, and determine the first feature pixel Pix1 and the second feature pixel Pix2 independently according to each feature boundary area BA.

In an embodiment of the present disclosure, the brightness threshold Lset and the feature number threshold Nset may be acquired by testing. For example, the picture containing the light-dark demarcation vertical line may be viewed in a preset environment, such as at a preset distance (e.g., 0.5 m) from the display panel PNL, at a preset viewing angle (e.g., directly in front), and the brightness threshold Lset and the feature number threshold Nset may be adjusted to make the light-dark demarcation vertical lines bright and dark, and the brightness threshold Lset and the feature number threshold Nset are adjusted so as to make jaggedness of the light-dark demarcation vertical line disappears or the degree of visibility thereof is reduced to an acceptable level.

In the embodiment of the present disclosure, the feature boundary area BA is determined by a difference in brightness between the first feature pixel Pix1 and the second feature pixel Pix2. Optionally, the brightness threshold Lset may be between 50 and 1000 nits, for example, it may be 50 nits. The brightness threshold of the display device may be determined by testing according to the usage scenario of the display panel and the requirement for quality.

In some embodiments of the present disclosure, the brightness of a pixel has a correspondence with a gray scale. Thus, the brightness of individual pixels can be determined based on the gray scale data of the pixel, and thus whether the difference in brightness between two adjacent pixels is greater than or equal to the brightness threshold Lset is determined based on the brightness of the pixel. In embodiments of the present disclosure, the brightness of individual sub-pixels can be determined based on the gray scales of the individual sub-pixels of the pixel; a sum of the brightnesses of the individual sub-pixels is the brightness of the pixel. In one example, the brightness of a sub-pixel may be determined based on the gray scale of the sub-pixel via a gamma curve.

In other embodiments of the present disclosure, the difference in brightness between the first feature pixel Pix1 and the second feature pixel Pix2 may be not a difference in brightness between the actual brightness of the first feature pixel Pix1 (the brightness that is actually displayed by the display panel) and the actual brightness of the second feature pixel Pix2 (the brightness that is actually displayed by the display panel), but also may be a difference in theoretical maximum brightness between the first feature pixel Pix1 and the second feature pixel Pix2, in order to reduce the calculation amount of the driving algorithm and to ensure that the feature boundary area BA is not missed. For example, the theoretical maximum brightness of a pixel may be determined based on the rated maximum brightness of the display panel and the gray scale data of the pixel without considering whether the display panel displays picture in accordance with the rated maximum brightness; in such a case, the difference in the theoretical maximum brightness between the first feature pixel Pix1 and the second feature, i.e., the brightness threshold Lset′ may be set between 40 nits-60 nits, or between 50 and 1000 nits, and may be 50 nits, for example. The control component CTR may be pre-stored with a gamma curve GAmax at the rated maximum brightness; after obtaining the gray scales of the individual sub-pixels of the pixel, the theoretical maximum brightnesses of the sub-pixels may be determined based on the gray scales of the sub-pixels and the gamma curve GAmax, and the theoretical maximum brightness of the pixel may be obtained based on the sum of the theoretical maximum brightnesses of the individual sub-pixels. For example, the rated maximum brightness of the display panel is between 300 and 1000 nits.

By way of example, a pixel includes three sub-pixels such as a red sub-pixel, a green sub-pixel, and a blue sub-pixel. In obtaining the gray scale data of the pixel, the gray scale of the red sub-pixel, the gray scale of the green sub-pixel, and the gray scale of the blue sub-pixel of the pixel may be obtained; then, based on the gray scale of the red sub-pixel and the gamma curve of the red sub-pixel under the rated maximum brightness, the theoretical maximum brightness of the red sub-pixel is determined; based on the gray scale of the green sub-pixel and the gamma curve of the green sub-pixel under the rated maximum brightness, the theoretical maximum brightness of the green sub-pixel is determined; based on the gray scale of the blue sub-pixel and the gamma curve of the blue sub-pixel under the rated maximum brightness, the theoretical maximum brightness of the blue sub-pixel is determined. Then, the sum of the theoretical maximum brightness of the red sub-pixel, the theoretical maximum brightness of the green sub-pixel and the theoretical maximum brightness of the blue sub-pixel is the theoretical maximum brightness of the pixel.

Of course, in other embodiments of the present disclosure, other methods may be employed to determine the brightness of the pixel (which may be an actual brightness, or may be a theoretical maximum brightness, or may be some other brightness associated with a gray scale).

In other embodiments of the present disclosure, other methods may also be used to determine the feature boundary area BA, such as using a grayscale threshold associated with a brightness threshold to determine whether two adjacent pixels may be used as a feature pixel group PixsA.

In the embodiments of the present disclosure, it is determined whether the number of feature pixel groups PixsA sequentially adjacent along the column direction DV exceeds the feature number threshold Nset to determine whether these feature pixel groups PixsA can form a feature boundary area BA; the essence of this determination is the overall length of the sequentially adjacent feature pixel groups PixsA in the vertical direction (column direction). Therefore, in other embodiments of the present disclosure, other ways may be used to determine whether these groups of feature pixels PixsA can form a feature boundary area BA, such as directly using the length as an indicator, or using other indicators related to the length.

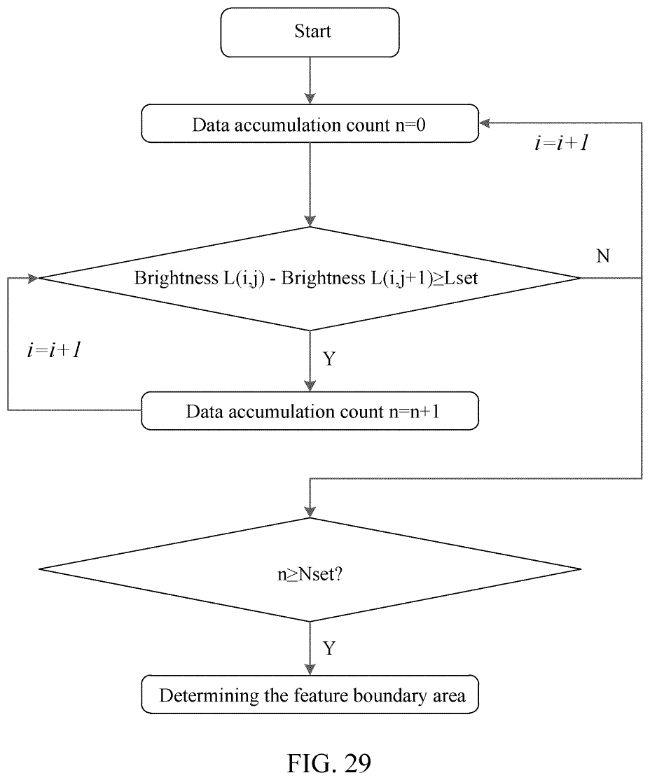

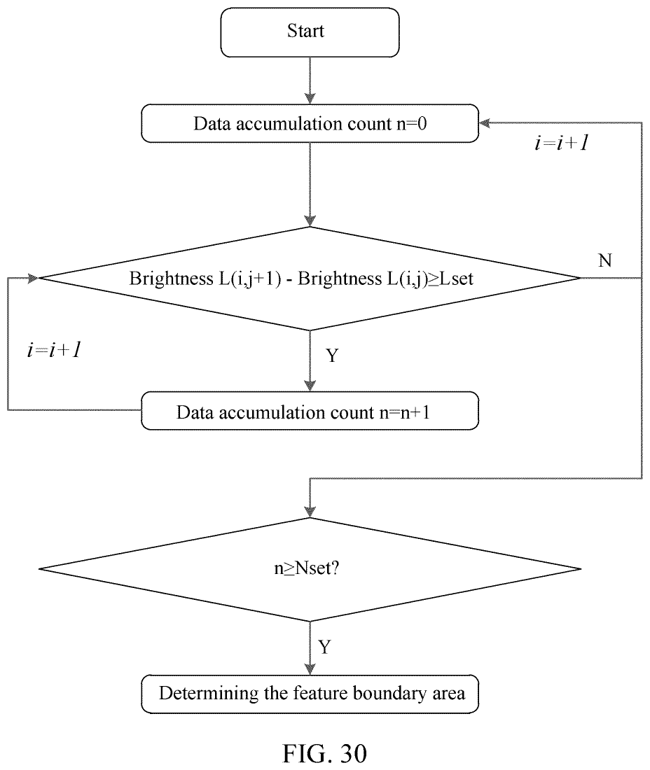

In one embodiment of the present disclosure, it is possible to sequentially determine whether a feature boundary area BA exists between two adjacent pixel columns. In determining whether a feature boundary area BA exists between any two adjacent pixel columns (e.g., a j-th column of pixels and a (j+1)-th column of pixels), the individual feature boundary areas BA can be obtained in accordance with the process shown in FIG. 29 and FIG. 30.

According to FIG. 29, a brightness L(i,j)−a brightness L(i,j+1) may be calculated, and it may be determined whether the brightness difference value is greater than or equal to a brightness threshold Lset. The brightness L(i,j) is the brightness of the pixel P(i,j) in the i-th row and the j-th column; and the brightness L(i,j+1) is the brightness of the pixel P(i,j+1) in the i-th row and the (j+1)-th column. If the brightness difference value is greater than or equal to the brightness threshold value, the data accumulation count n is increased by 1. At this time, pixel P(i,j) and pixel P(i,j+1) can be used as a set of feature pixel groups PixsA, and pixel P(i,j) is a first feature pixel Pix1 and pixel P(i,j+1) is a second feature pixel Pix2. The data accumulation count n is used to record a number of continuously adjacent feature pixel groups PixsA along the column direction DV, and is further used to determine whether these feature pixel groups PixsA can form a feature boundary area BA. Referring to FIG. 29, if the brightness difference value is greater than or equal to the brightness threshold value, pixel P(i,j) and pixel P(i,j+1) are not treated as a set of a feature pixel groups PixsA in the process; at this time, the current data accumulation count n is number of continuous feature pixel groups PixsA, and by determining whether the current data accumulation count n is greater than the feature number threshold Nset, it can be determined whether the current continuous feature pixel groups PixsA can be used as a feature boundary area BA. If the current data accumulation count n is greater than the feature number threshold value Nset, these feature pixel groups PixsA can be formed into a feature boundary area BA. Further, the feature boundary area BA including these feature pixel groups PixsA may be recorded so that the transition area TA may be determined by calling, referencing, or looking up these feature boundary areas BA. For example, a first pixel Pix (i.e., the pixel with the smallest row position and column position) of a feature boundary area BA and the number of the feature pixel groups PixsA in the feature boundary area BA may be recorded and then the feature boundary area BA may be recorded. Not only that, referring to FIG. 29, if pixel P(i,j) and pixel P(i,j+1) cannot be treated as a set of feature pixel groups PixsA in the process, the data accumulation count n needs to be reset to 0. The current data accumulation count n is the data before the reset. Regardless of whether pixel P(i,j) and pixel P(i,j+1) are treated as a set of feature pixel group PixsA in the process, i is accumulated by 1, i.e., it starts comparing two pixels in the next pixel row until the last pixel row is reached (i.e., i reaches the maximum value I, which is the number of pixel rows of the display panel PNL). The feature boundary area BA thus obtained has the pixel in the previous column as the first feature pixel Pix1 and the pixel in the following column as the second feature pixel Pix2, and the number of the continuous feature pixel groups PixsA is not less than the feature number threshold Nset. After completing the comparison of the brightness of pixels in the two columns, it continues to carry out the comparison of the brightness of the pixels in the other two adjacent columns until completing the comparison of the brightness of any two pixels adjacent along the row direction.

According to FIG. 30, a brightness L(i,j+1)-a brightness L(i,j) can be calculated, and it may be determined whether the brightness difference value is greater than or equal to a brightness threshold value. The brightness L(i,j) is the brightness of the pixel P(i,j) in the i-th row and the j-th column; and the brightness L(i,j+1) is the brightness of the pixel P(i,j+1) in the i-th row and the (j+1)-th column. If the brightness difference value is greater than or equal to the brightness threshold value, the data accumulation count n is increased by 1. At this time, pixel P(i,j) and pixel P(i,j+1) can be used as a set of feature pixel groups PixsA, and pixel P(i,j) is a second feature pixel Pix2 and pixel P(i,j+1) is a first feature pixel Pix1. The data accumulation count n is used to record a number of continuously adjacent feature pixel groups PixsA along the column direction DV, and is further used to determine whether these feature pixel groups PixsA can form a feature boundary area BA. Referring to FIG. 30, if the brightness difference value is greater than or equal to the brightness threshold value, pixel P(i,j) and pixel P(i,j+1) are not treated as a set of a feature pixel groups PixsA in the process; at this time, the current data accumulation count n is number of constinuous feature pixel groups PixsA, and by determining whether the current data cumulative count n is greater than the feature number threshold Nset, it can be determined whether the current continuous feature pixel groups PixsA can be used as a feature boundary area BA. If the current data cumulative count n is greater than the feature number threshold value Nset, these feature pixel groups PixsA can be formed into a feature boundary area BA. Further, the feature boundary area BA including these feature pixel groups PixsA may be recorded so that the transition area TA may be determined by calling, referencing, or looking up these feature boundary areas BA. For example, a first pixel Pix (i.e., the pixel with the smallest row position and column position) of a feature boundary area BA and the number of the feature pixel groups PixsA in the feature boundary area BA may be recorded, and then the feature boundary area BA may be recorded. Not only that, referring to FIG. 30, if pixel P(i,j) and pixel P(i,j+1) cannot be treated as a set of feature pixel groups PixsA in the process, the data accumulation count n needs to be reset to 0. The current data accumulation count n is the data before the reset. Regardless of whether pixel P(i,j) and pixel P(i,j+1) are treated as a set of feature pixel group PixsA in the process, i is accumulated by 1, i.e., it starts comparing the two pixels of the next pixel row until the last pixel row is reached (i.e., i reaches the maximum value I, which is the number of pixel rows of the display panel PNL). The feature boundary area BA thus obtained has the pixel in the previous column as the second feature pixel Pix2 and the pixel in the following column as the first feature pixel Pix1, and the number of the continuous feature pixel groups PixsA is not less than the feature number threshold Nset. After completing the comparison of the brightness of pixels in two columns, it continues to carry out the comparison of the brightness of the pixels in the other two adjacent columns until completing the comparison of the brightness of any two pixels adjacent along the row direction.

In one example, when the initial picture is shown in FIG. 19-1, a checkerboard pattern is presented in the initial picture having light-dark demarcation vertical lines of black and white pictures. The pictures on both sides of the light-dark demarcation vertical line have a large brightness difference (e.g., a gray scale difference of 255 and a brightness difference of more than 50 nits) and have a large length (e.g., a length of 100 pixel rows or more), and thus there are feature boundary areas BA at the light-dark demarcation vertical lines. Each feature boundary area BA has a column of pixels displaying white (first feature pixel Pix1) and a column of pixels displaying black (second feature pixel Pix2). At the intersection of the light-dark demarcation vertical lines and the lateral demarcation line, the columns of black pixels and the columns of white pixels alternate, so that the light-dark demarcation vertical lines above and below the lateral demarcation line are located in two different feature boundary areas BA, and the transition areas TA can be determined independently of each other.

In one example, before determining whether the brightness difference between any two adjacent pixels is greater than or equal to the brightness threshold value, it may also be determined whether both pixels are gray pixels (each sub-pixel of a gray pixel has the same gray scale). When either pixel is not a gray pixel, the judgment of the brightness difference between the two pixels may not be initiated; when both pixels are gray pixels, then the judgment of the brightness difference between the two pixels may be initiated. In this way, the embodiment may be targeted applicable to eliminate or attenuate the jaggedness between the gray patterns. It will be appreciated that when the gray scales of the individual sub-pixels are all 0, the gray pixel is a non-illuminated black pixel; and when the gray scales of the individual sub-pixels are a maximum gray scale (e.g., 255), the gray pixel is a white pixel with maximum brightness.

In one embodiment of the present disclosure, the difference in brightness between the first feature pixel Pix1 and the second feature pixel Pix2 is the difference in theoretical maximum brightness between the first feature pixel Pix1 and the second feature pixel Pix2; the brightness threshold value is 50 nits, and the feature number threshold Nset is 5.

In another embodiment of the present disclosure, the difference in brightness between the first feature pixel Pix1 and the second feature pixel Pix2 is a difference in actual brightness between the first feature pixel Pix1 and the second feature pixel Pix2; the brightness threshold value is 50 nits, and the feature number threshold Nset is 5.

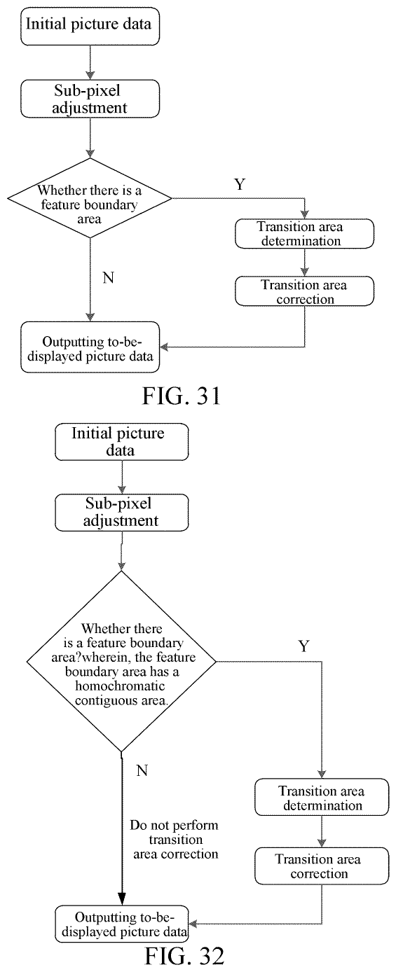

In one embodiment of the present disclosure, referring to FIG. 31, the driving method of an embodiment of the present disclosure may further include:

Step S160, in step S120, if the feature boundary area BA is not acquired, i.e., the number of feature boundary areas BA is 0, the display panel PNL is driven based on the picture data in step S110. In this way, if there is no feature boundary area BA based on the picture data, it is indicated that the picture does not need to be subjected to a transition area correction. In the example of FIG. 31, the initial picture data is first subjected to sub-pixel adjusting to obtain the post-adjustment picture data, and this post-adjustment picture data is used as the picture data in step S110. In other examples of the present disclosure, if the picture data is not subjected to sub-pixel adjustment, for example the picture data is the initial picture data, the picture data needs to subject to sub-pixel adjustment to form the post-adjustment picture data, and the post-adjustment picture data is output to the display panel PNL as the picture data to be displayed.

In some embodiments of the present disclosure, referring to FIG. 31, after obtaining the feature boundary area BA, a transition area TA corresponding to the feature boundary area BA is directly determined, and then a transition area correction is performed according to the transition area TA. If the feature boundary area BA does not exist, then there is no need to determine the transition area TA and there is no need to perform the transition area correction.

In other embodiments of the present disclosure, referring to FIG. 32, in obtaining the feature boundary area BA, it is also necessary to make the feature boundary area have a homochromatic contiguous area CA. The homochromatic contiguous area CA is adjacent to at least one column of pixels in the feature boundary area BA and has the same color and gray scale.

For example, in obtaining the feature boundary area BA, it is also necessary to make the feature pixel group PixsA have a homochromatic contiguous pixel; if the brightness difference value between two pixels adjacent along the row direction is greater than or equal to a brightness threshold value, but the two pixels do not have a homochromatic contiguous pixel, then the two pixels are not used as the feature pixel group PixsA of the embodiment. The homochromatic contiguous pixel means one or more pixels that are sequentially adjacent to the first feature pixel Pix1 in the same row and have the same data (same color and gray scale) as the first feature pixel Pix1 (i.e., homochromatic contiguous pixels of the first feature pixel Pix1), and one or more pixels that are sequentially adjacent to the second feature pixel Pix2 in the same row and have the same data (color and gray scale are the same) with the second feature pixel Pix2 (i.e., homochromatic contiguous pixels of the second feature pixel Pix2).

In determining whether a plurality of feature pixel groups PixsA adjacent in the same column can be used as the feature boundary area BA, it is also necessary to determine whether the homochromatic contiguous pixels of these feature pixel groups PixsA can form a homochromatic contiguous area CA of the feature boundary area BA. The homochromatic contiguous area CA of the feature boundary area BA refers to an area consisting of one or more columns of homochromatic contiguous pixels when the individual first feature pixels Pix1 of the feature boundary area BA have the homochromatic contiguous pixels, and refers to an area consisting of one or more columns of homochromatic contiguous pixels when the individual second feature pixels Pix2 of the feature boundary area BA have homochromatic contiguous pixels. In other words, the homochromatic contiguous area CA is adjacent to at least one column of pixels in the feature boundary area BA and of the same color and gray scale as at least one column of pixels in the feature boundary area BA. Two pixels having the same grayscale and color may be the sub-pixel grayscale data of these two pixels being same, for example, the grayscales of red sub-pixels of the two pixels are same, the grayscales of green sub-pixels of the two pixels are same, and the grayscales of blue sub-pixels of the two pixels are same.

In this way, the feature boundary area BA and its homochromatic contiguous area CA can form a solid-color picture (e.g., a red, yellow, white, green, magenta, dark green, purple, or other picture) having a width of at least two columns of pixels. This can avoid correcting the gray scale of the single-pixel column pattern, and thus avoid degrading the display effect of the single-pixel column pattern. In an embodiment of the present disclosure, a solid color picture refers to a picture in which the individual pixels have the same color and same gray scale.

In one embodiment of the present disclosure, the solid color picture may be a gray picture. In a gray picture, the individual pixels are gray pixels, and the individual sub-pixels of the gray pixels have the same gray scale. For example, the gray picture may be a white picture (where the individual sub-pixels have a maximum gray scale, such as 255), a black picture (where the individual pixels have a gray scale of 0), or a gray picture where the individual sub-pixels have a gray scale of 128, and the like.

In one embodiment of the present disclosure, the homochromatic contiguous pixels of the feature pixel groups PixsA may further include one or more pixels that are sequentially adjacent to the first feature pixel Pix1 in a same row and have similar data (similar color and gray scale) to the first feature pixel Pix1 (i.e., the homochromatic contiguous pixels of the first feature pixel Pix1), and one or more pixels that are sequentially adjacent to the second feature pixel Pix2 in a same row and have similar data (similar color and gray scale) to the second feature pixel Pix2 (i.e., the homochromatic contiguous pixels of the second feature pixel Pix2). The criterion for “similar” is that there is no obvious transition between the homochromatic contiguous pixels and at least one column of pixels in the feature boundary area BA in the image directly displayed on the initial picture for the human eyes. In this way, the scope of application of the “the homochromatic contiguous area” can be expanded without departing from the main purpose and intent protected by the present disclosure, thereby achieving good display effect. In one embodiment of the present disclosure, in step S120, the feature boundary area BA and the homochromatic contiguous area CA of the feature boundary area BA can be obtained based on the gray scales of the pixels Pix in the picture data.

In one example, in step S120, in obtaining the feature boundary area BA, it is necessary to make the feature boundary area BA satisfy the following conditions:
In each feature pixel group PixsA, the difference in brightness between the first feature pixel Pix1 and the second feature pixel Pix2 is greater than or equal to the brightness threshold value Lset;
Each feature pixel group PixsA has a homochromatic contiguous pixel of the first feature pixel Pix1, or each feature pixel group PixsA has a homochromatic contiguous pixel of the second feature pixel Pix2, or each feature pixel group PixsA has a homochromatic contiguous pixel of the first feature pixel Pix1 and each feature pixel group PixsA has a homochromatic contiguous pixel of the second feature pixel Pix2. This ensures that the homochromatic contiguous pixels can form the homochromatic contiguous area CA. Of course, each feature pixel group PixsA has a homochromatic contiguous pixel of the first feature pixel Pix1;
In one embodiment of the present disclosure, in step S130, a transition area TA corresponding to the feature boundary area BA may be determined based on the feature boundary area BA and the homochromatic contiguous area CA of the feature boundary area BA;
In one embodiment of the present disclosure, referring to FIGS. 20 to 28, the homochromatic contiguous area CA of the feature boundary area BA includes at least one of a first homochromatic contiguous area CAL and a second homochromatic contiguous area CA2. The first homochromatic contiguous area CA1 includes first homochromatic pixel groups PixsB corresponding one-to-one to the individual feature pixel groups PixsA of the feature boundary area BA; the first homochromatic pixel groups PixsB are adjacent to corresponding first feature pixels Pix1 of the feature pixel group PixsA in a same row and of the same color and grayscale, and includes one or more third feature pixels Pix3 (i.e., homochromatic contiguous pixels of the first feature pixel Pix1); the second homochromatic contiguous area CA2 includes second homochromatic pixel groups PixsC corresponding one-to-one to the individual feature pixel groups PixsA of the feature boundary area BA; the second homochromatic pixel groups PixsC are adjacent to the corresponding second feature pixels Pix2 of the feature pixel group PixsA in a same row and of same color and gray scale, and includes one or more fourth feature pixels Pix4 (i.e., homochromatic contiguous pixels of the second feature pixel Pix2).

In one example, colors of individual first feature pixels Pix1 in a same feature boundary area BA are same; further, grayscales of individual first feature pixels Pix1 are same. Thus, the first feature pixel Pix1 of the feature boundary area BA and the respective third feature pixels Pix3 in the first homochromatic contiguous area CAL of the feature boundary area BA are displayed with the same color and gray scale, and thus a monochromatic pattern block can be displayed.

In one example, colors of individual second feature pixels Pix2 in a same feature boundary area BA are same; further, grayscales of individual second feature pixels Pix2 are same. In this way, the second feature pixel Pix2 of the feature boundary area BA and the respective fourth feature pixels Pix4 of the second homochromatic contiguous area CA2 of the feature boundary area BA are displayed with the same color and gray scale, and thus a monochromatic pattern block can be displayed.

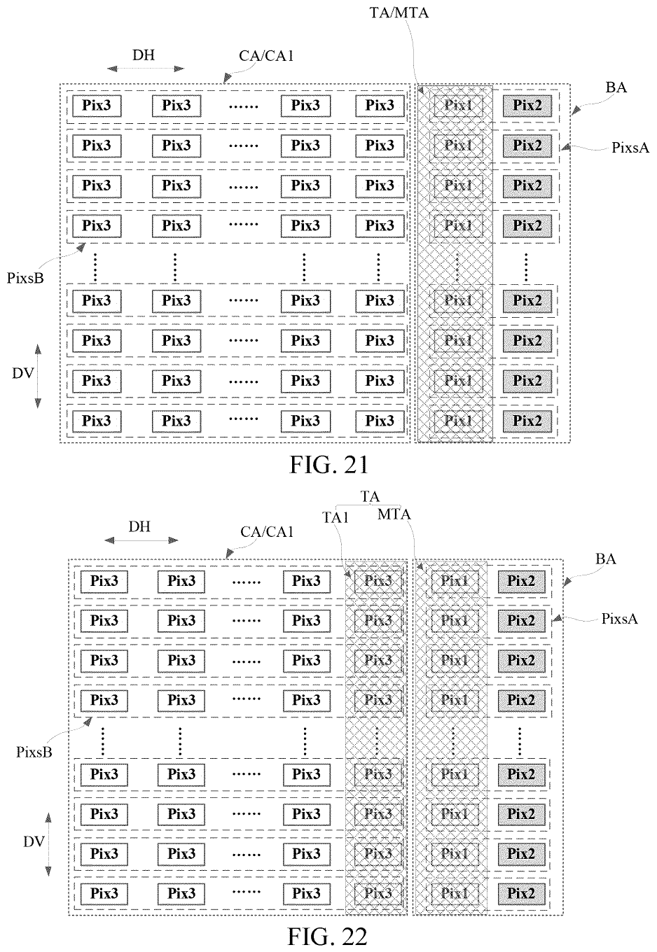

In one embodiment of the present disclosure, when the homochromatic contiguous area CA of the feature boundary area BA includes a first homochromatic contiguous area CA1, step S130 includes:
Referring to FIG. 21, determining that the transition area TA corresponding to the feature boundary area BA includes individual first feature pixels Pix1 of the feature boundary area BA;
Correcting gray scales of at least part of the pixels Pix of the transition area TA corresponding to the feature boundary area BA includes:
obtaining corrected gray scales of individual first feature pixels Pix1 by reducing gray scales of the individual first feature pixels Pix1 of the feature boundary area BA; the corrected gray scale of the first feature pixel Pix1 is greater than the gray scale of the second feature pixel Pix2 in the same feature pixel group PixsA. Further, it is possible to make a brightness difference value between the brightness corresponding to the corrected gray scale of the first feature pixel Pix1 and the brightness corresponding to the gray scale of the second feature pixel Pix2 greater than or equal to a brightness threshold value, and to make a brightness difference value between the brightness corresponding to the gray scales of the pixels adjacent in a same row in the first homochromatic contiguous area CAL and the brightness corresponding to the corrected gray scale of the first feature pixel Pix1 greater than or equal to a brightness threshold value. In this way, a jaggedness of the light-dark demarcation vertical lines in the feature boundary area BA can be eliminated or attenuated, and a light-dark demarcation vertical line with a distinct jaggedness between the feature boundary area BA and the first homochromatic contiguous area CA1 can also be avoided.

In one example, correcting the gray scales of at least part of pixels Pix of a transition area TA corresponding to the feature boundary area BA (step S140) may include:
obtaining corrected gray scales Gn(Pix1) of individual first feature pixels Pix1 by reducing the gray scales of individual first feature pixels Pix1 of the feature boundary area BA, and

$$G ( Pi x 2 ) + 0 . {3}^{*} ( G ( P i x 1 ) - G ( P i x 2 ) ) < G n ( Pix 1 ) < G ( Pix 1 ) - {0.3}^{*} ( G ( P i x 1 ) - G ( P i x 2 ) ) ;$$

where G(Pix1) is the gray scale of the first feature pixel Pix1 before correction; and G(Pix2) is the gray scale of the second feature pixel Pix2 before correction. In this way, the corrected gray scale Gn(Pix1) is near the middle position of G(Pix1) and G(Pix2), and a gray scale transition (i.e., a brightness transition) between the second feature pixel Pix2 and the first homogeneous contiguous area CA1 can be effectively realized, so that the jaggedness of the light-dark demarcation vertical line between the first homogeneous contiguous area CA1 and the second feature pixel Pix2 is attenuated or eliminated.

In a further example, in the case where the homochromatic contiguous area CA of the feature boundary area BA includes the first homochromatic contiguous area CA1, only the gray scale of the first feature pixel Pix1 of the feature boundary area BA may be corrected without correcting the gray scales of the individual pixels of the first homochromatic contiguous area CA1. In other words, in the example, when there is a first homochromatic contiguous area CA1 in the feature boundary area BA, only the gray scale of the first feature pixel Pix1 in the feature boundary area BA may be corrected to achieve correction of the transition area.

In one example, the corrected gray scale Gn(Pix1) may be a rounding of an arithmetic mean of G(Pix1) and G(Pix2).

In one embodiment of the present disclosure, when the first homochromatic contiguous area CA1 includes only one column of pixels, the gray scales of the pixels in the first homochromatic contiguous area CA1 are not corrected.

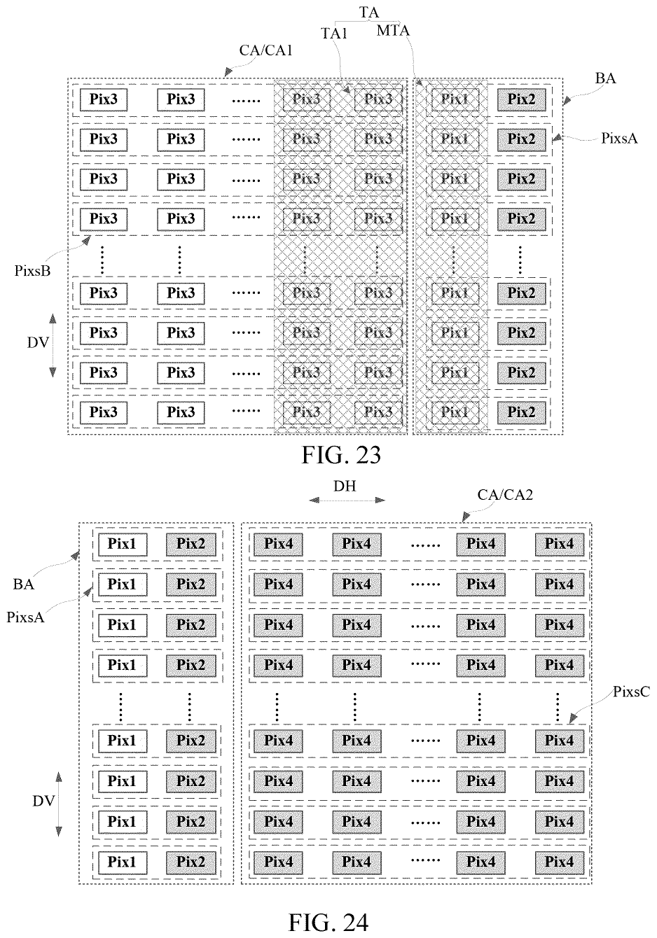

In another embodiment of the present disclosure, referring to FIGS. 22 and 23, when the homochromatic contiguous area CA of the feature boundary area BA includes a first homochromatic contiguous area CA1 and the first homochromatic contiguous area CA1 includes a plurality of columns of pixels, step S130 includes:
determining that the transition area TA corresponding to the feature boundary area BA includes a first transition area MTA and a second transition area TA1; the first transition area MTA includes individual first feature pixels Pix1 of the feature boundary area BA; the second transition area TA1 includes at least one column of pixels in the first homochromatic contiguous area CA1 adjacent to the first transition area MTA, and at least one column of pixels Pix in the first homochromatic contiguous area CA1 does not belong to the second transition area TA1;
Correcting the gray scales of at least some of the pixels Pix of the transition area TA corresponding to the feature boundary area BA includes:
obtaining corrected gray scales of individual pixels by reducing the gray scales of the individual pixels in the transition area TA, and such that the corrected gray scales of individual pixels in any row of the transition area TA decreases sequentially (e.g., iso-gray scale gradient decreases) in a direction pointing from the first homochromatic contiguous area CA1 to the feature boundary area BA, and the corrected gray scale of the first feature pixel Pix1 is greater than the gray scale of the second feature pixel Pix2.

In this way, the boundary transition between the first homochromatic contiguous area CA1 and the second feature pixel Pix2 can be achieved by means of a plurality of columns of pixels, which can make the boundary transition smoother, and in particular can be advantageous to ensure that the brightness difference between two adjacent columns of pixels is small.

Optionally, the number of columns of pixels included in the transition area TA may be determined as needed. For example, the number of columns may be one of 2, 3, 4. In one example, the number of pixel columns in the respective transition area TA is predetermined. In another example, the number of pixel columns in the respective transition areas TA may be independently determined based on the number of pixel columns included in the first homochromatic contiguous area CA1, and the magnitude of the grayscale difference between the first feature pixel Pix1 and the second feature pixel Pix2. For example, the larger the brightness difference between the first feature pixel Pix1 and the second feature pixel Pix2, the larger the number of pixel columns in the transition area TA.

In one example, correcting the gray scales of at least part of the pixels Pix of the transition area TA corresponding to the feature boundary area BA (step S140) includes:
determining the corrected gray scale of any one pixel in the transition area TA according to the following formula:

$$Gn ( q ) = round ( G ( Pix 1 ) - {q}^{*} ( ( G ( P i x 1 ) - G ( P i x 2 ) ) / ( Q + 1 ) ) ;$$

where Gn(q) is the corrected gray scales of the q-th column of pixels P(q) in the transition area TA along a direction pointing from the first homochromatic contiguous area CA1 to the feature boundary area BA; G(Pix1) is the gray scale of the first feature pixel Pix1 on the same row as pixel P(q); G(Pix2) is the gray scale of the second feature pixel Pix2 on the same row as pixel P(q); Q is the number of columns of pixels included in the transition area TA, Q is a positive integer not less than 2; q is a positive integer from 1 to Q, and round( ) denotes rounding to the nearest whole number.

Of course, in this embodiment, it is also possible to make the second transition area TA1 include no pixels, then Q=1. In this way, the method of this embodiment can also be applied to the case where only one column of pixels is included in the first homochromatic contiguous area CA1, and in this case, only the gray scale of the first feature pixel Pix1 is corrected.

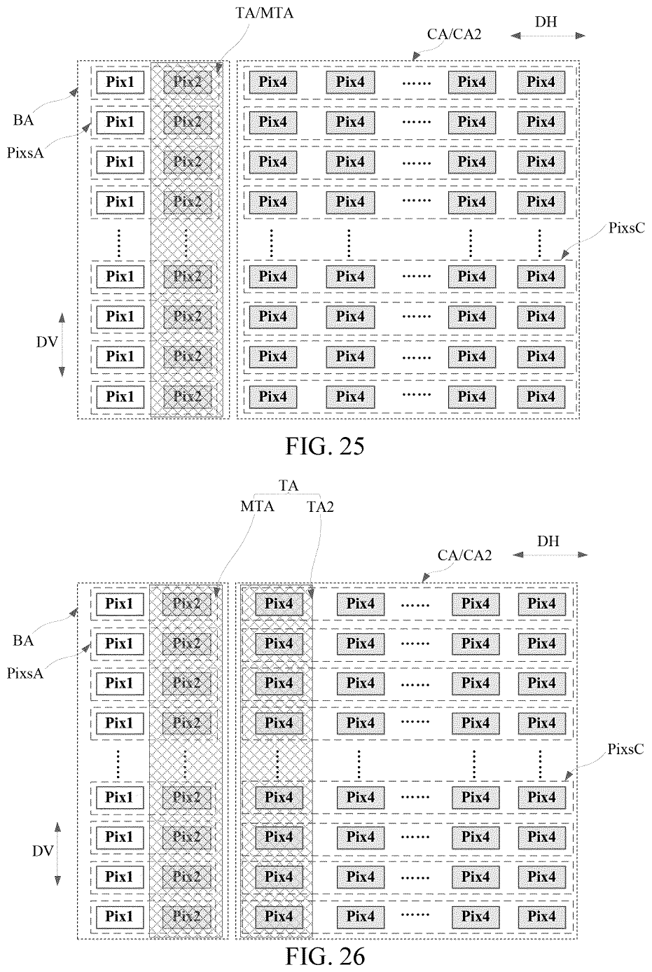

In one embodiment of the present disclosure, referring to FIGS. 24 and 25, when the homochromatic contiguous area CA of the feature boundary area BA includes a second homochromatic contiguous area CA2, step S130 includes:
determining that a transition area TA corresponding to the feature boundary area BA includes individual second feature pixels Pix2 of the feature boundary area BA;
correcting gray scales of at least part of the pixels Pix of the transition area TA corresponding to the feature boundary area BA includes:
obtaining corrected gray scales of individual second feature pixels Pix2 by increasing the gray scales of individual second feature pixels Pix2 of the feature boundary area BA; the corrected gray scale of the second feature pixel Pix2 is less than the gray scale of the first feature pixel Pix1 in the same feature pixel group PixsA.

Further, it is possible to make the brightness difference value between the brightness corresponding to the gray scale of the first feature pixel Pix1 and the brightness corresponding to the corrected gray scale of the second feature pixel Pix2 greater than or equal to a brightness threshold value LSet, and to try to make the brightness difference value between the brightness corresponding to the corrected gray scale of the second feature pixel Pix2 and the brightness corresponding to the gray scale of the pixel adjacent in a same row in the second homochromatic contiguous area CA2 greater than or equal to the brightness threshold value Lset. In this way, visible jaggedness of the light-dark demarcation vertical lines within the feature boundary area BA can be eliminated, and light-dark demarcation vertical lines with visible jaggedness between the feature boundary area BA and the second homochromatic contiguous area CA2 can also be avoided.

In one example, correcting the gray scales of at least part of pixels Pix of a transition area TA corresponding to the feature boundary area BA (step S140) may include:
obtaining corrected gray scales Gn(Pix2) of individual second feature pixels Pix2 by increasing the gray scales of individual second feature pixels Pix2 of the feature boundary area BA, and

$$G ( Pix 2 ) + 0 . {3}^{*} ( G ( P i x 1 ) - G ( P i x 2 ) ) < G n ( Pix 2 ) < G ( Pix 1 ) - {0.3}^{*} ( G ( P i x 1 ) - G ( P i x 2 ) ) ;$$

where G(Pix1) is the gray scale of the first feature pixel Pix1 before correction; and G(Pix2) is the gray scale of the second feature pixel Pix2 before correction. In this way, the corrected gray scale Gn(Pix2) is near the middle position of G(Pix1) and G(Pix2), and a gray scale transition between the first feature pixel Pix1 and the second homochromatic contiguous area CA2 can be effectively realized, so that the jaggedness of the boundary line between the second homochromatic contiguous area CA2 and the first feature pixel Pix1 is attenuated or eliminated.

In a further example, in the case where the homochromatic contiguous area CA of the feature boundary area BA includes the second homochromatic contiguous area CA2, only the gray scale of the second feature pixel Pix2 of the feature boundary area BA may be corrected without correcting the gray scales of the individual pixels of the second homochromatic contiguous area CA2. In other words, in the example, when the second homochromatic contiguous area CA2 exists in the feature boundary area BA, only the gray scale of the second feature pixel Pix2 in the feature boundary area BA may be corrected to achieve correction of the transition area.

In further examples, the corrected gray scale Gn(Pix2) may be a rounding of an arithmetic mean of G(Pix1) and G(Pix2).

In one embodiment of the present disclosure, when the second homochromatic contiguous area CA2 includes only one column of pixels, the gray scales of the pixels in the second homochromatic contiguous area CA2 are not corrected.

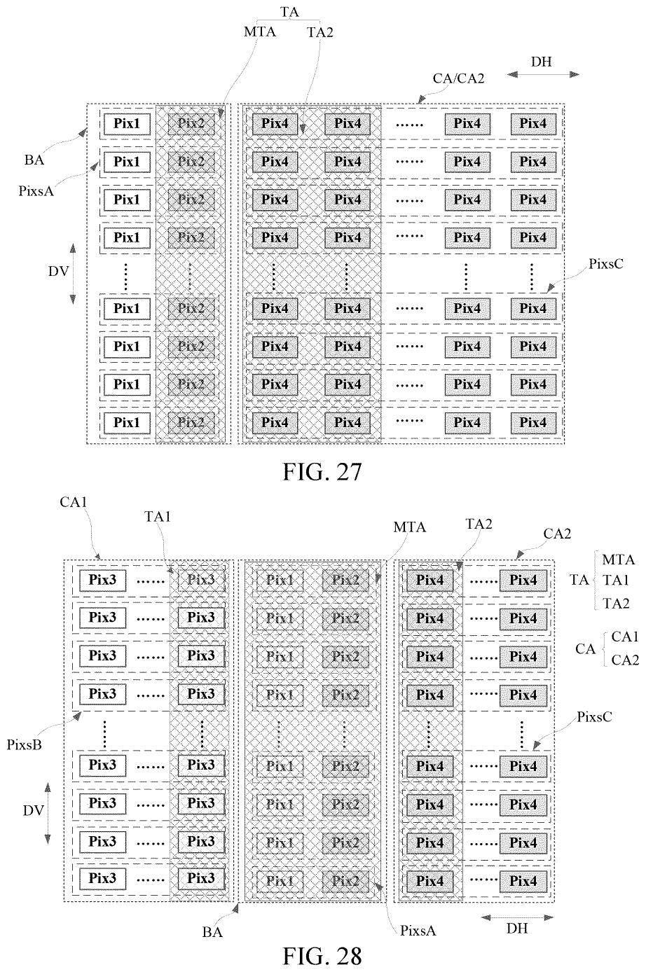

In another embodiment of the present disclosure, referring to FIGS. 26 and 27, when the homochromatic contiguous area CA of the feature boundary area BA includes a second homochromatic contiguous area CA2 and the second homochromatic contiguous area CA2 includes a plurality of columns of pixels, step S130 includes:
determining that the transition area TA corresponding to the feature boundary area BA includes a first transition area MTA and a third transition area TA2; the first transition area MTA includes individual second feature pixels Pix2 of the feature boundary area BA; the third transition area TA2 includes at least one column of pixels in the second homochromatic contiguous area CA2 adjacent to the first transition area MTA, and at least one column of pixels Pix in the second homochromatic contiguous area CA2 does not belong to the third transition area TA2;
Correcting the gray scales of at least part of the pixels Pix of the transition area TA corresponding to the feature boundary area BA includes:
obtaining corrected gray scales of individual pixels by increasing the gray scales of individual pixels in the transition area TA, and such that the corrected gray scales of individual pixels in any row of the transition area TA increases sequentially (e.g., iso-gray scale gradient increases) along the direction pointing from the second homochromatic contiguous area CA2 to the feature boundary area BA, and that the corrected gray scale of the second feature pixel Pix2 is less than the gray scale of the first feature pixel Pix1.

In this way, the boundary transition between the second homochromatic contiguous area CA2 and the first feature pixel Pix1 can be realized by means of a plurality of columns of pixels, which can make the boundary transition smoother.

In one example, the number of pixel columns in respective transition areas TA may be independently determined based on the number of pixel columns included in the second homochromatic contiguous area CA2, and the magnitude of the grayscale difference between the first feature pixel Pix1 and the second feature pixel Pix2. For example, the larger the gray scale difference between the first feature pixel Pix1 and the second feature pixel Pix2, the larger the number of pixel columns in the transition area TA.

In one example, correcting the gray scale of at least part of the pixels Pix of the transition area TA corresponding to the feature boundary area BA (step S140) includes:
determining the corrected gray scale of any one pixel in the transition area TA according to the following formula:

$$Gn ( t ) = round ( G ( Pix 1 ) - {t}^{*} ( ( G ( P i x 1 ) - G ( P i x 2 ) ) / ( T + 1 ) ) ;$$

where Gn(t) is the corrected gray scales of the t-th column of pixels P(t) in the transition area TA along a direction pointing from the second homochromatic contiguous area CA2 to the feature boundary area BA; G(Pix1) is the gray scale of the first feature pixel Pix1 on the same row as pixel P(t); G(Pix2) is the gray scale of the second feature pixel Pix2 on the same row as pixel P(t); and T is the number of columns of pixels included in the transition area TA, Tis a positive integer not less than 2; t is a positive integer from 1 to T.

Of course, in this embodiment, it is also possible to make the third transition area TA2 include no pixels, then T=1. In this way, the method of this embodiment can also be applied to the case where only one column of pixels is included in the second homochromatic contiguous area CA2, and in this case, only the grayscale of the second feature pixel Pix2 is corrected.

In one embodiment of the present disclosure, as long as the homochromatic contiguous area CA of the feature boundary area BA includes the first homochromatic contiguous area CA1, only the gray scales of individual first feature pixels Pix1 of the feature boundary area BA are corrected, or only the gray scales of individual first feature pixels Pix1 of the feature boundary area BA and the gray scales of individual pixels of the second transition area TA1 are corrected.

In another embodiment of the present disclosure, as long as the homochromatic contiguous area CA of the feature boundary area BA includes a second homochromatic contiguous area CA2, only the gray scales of individual second feature pixels Pix2 of the feature boundary area BA are corrected, or only the gray scales of individual second feature pixels Pix2 of the feature boundary area BA and the gray scales of the individual pixel of the third transition area TA2 are corrected.

In another embodiment of the present disclosure, referring to FIG. 28, when the homochromatic contiguous area CA of the feature boundary area BA includes a first homochromatic contiguous area CA1 and a second homochromatic contiguous area CA2, it is also possible to make the transition area TA corresponding to the feature boundary area BA include a second transition area TA1, a first transition area MTA, and a third transition area TA2. After the correction of the transition area, the corrected gray scales of individual pixels in one same row in the transition area TA can be made to decrease sequentially along the direction from the second transition area TA1 to the third transition area TA2; where the corrected gray scale of the pixel in the second transition area TA1 that is furthest away from the first transition area MTA is less than the gray scale of the third feature pixel Pix3 before correction; the corrected gray scale of the pixel in the third transition area TA2 that is furthest away from the first transition area MTA is larger than the gray scale of the fourth feature pixel Pix4 before correction.

In one embodiment of the present disclosure, after obtaining the corrected gray scale of the pixel, the grayscale data of a sub-pixel of the corrected pixel can be determined based on the uncorrected gray scale and the corrected gray scale of the pixel. For example, the gray scale data of individual sub-pixels are corrected in equal proportions according to the correction ratio of the gray scale of the pixel. If an integer cannot be obtained when the sub-pixels are corrected proportionally, rounding can be performed.

For example, GnR=round(GR*Gn/G), GnG=round(GG*Gn/G), and GnB=round(GB*Gn/G). Where, Gn is the gray scale of the pixel after correction; G is the gray scale of the pixel before correction; GR is the gray scale of the red sub-pixel before correction, GnR is the gray scale of the red sub-pixel after correction; GG is the gray scale of the green sub-pixel before correction, GnG is the gray scale of the green sub-pixel after correction; GB is the gray scale of the blue sub-pixel before correction, and GnB is the gray scale of the blue sub-pixel after correction.

In one embodiment of the present disclosure, the control component CTR may determine the gray scale of the pixel based on the brightness of the pixel according to the gamma curve of the pixel. As follows, a driving method of one embodiment of the present disclosure is illustrated exemplarily using the picture shown in FIG. 9-1 as an example. Referring to FIG. 9-1, the picture is a black-and-white square picture (checkerboard picture). In the area circled by the dotted line in FIG. 9-1, there exists a light-dark demarcation vertical line FIGA and a light-dark demarcation vertical line FIGB between the black-and-white picture. In a conventional display, the gray scales of the pixels on both sides of the light-dark demarcation vertical line FIGA and the light-dark demarcation vertical line FIGB are not corrected, which makes the light-dark demarcation vertical line FIGA and the light-dark demarcation vertical line FIGB have a distinct jagged feeling. When adopting the driving method provided in the embodiment of the present disclosure, a brightness threshold of 50 nits and a feature number threshold of 5 may be set. After obtaining the picture data, it may be found by comparison that the difference in brightness between the two sides of the light-dark demarcation vertical line FIGA is greater than 50 nits, and that the length of the light-dark demarcation vertical line FIGA is greater than 5 rows in the column direction, so that the light-dark demarcation vertical line FIGA is located in the corresponding feature boundary area. Through comparison, it can be found that the brightness difference between the two sides of the light-dark demarcation vertical line FIGB is greater than 50 nits, and the length of the light-dark demarcation vertical line FIGB is greater than 5 rows in the column direction, so the light-dark demarcation vertical line FIGB is located in the corresponding feature boundary area. A gray-scale transition correction may be performed according to the feature boundary area corresponding to the light-dark demarcation vertical line FIGA. Specifically, a gray-scale value of a column of pixels having a gray-scale of 255 that is nearest to the light-dark demarcation vertical line FIGA is reduced, for example to 128. A gray-scale transition correction may be performed according to the feature boundary area corresponding to the light-dark demarcation vertical line FIGB. Specifically, a gray scale value of the column of pixels having a gray scale of 255 that is nearest to the light-dark demarcation vertical line FIGB is reduced, for example, to 128. When display is performed based on the picture after gray scale correction, the displayed picture is shown in FIG. 9-2; referring to FIG. 9-2, the jaggedness at the light-dark demarcation vertical line FIGA and the light-dark demarcation vertical line FIGB disappears. This shows that the embodiment of the present disclosure can eliminate the jaggedness at the light-dark demarcation vertical line by means of pixel gray scale transition. In one embodiment of the present disclosure, the control component CTR includes a data handling unit DHU, and the data handling unit DHU includes:

a data caching unit MU1 configured to acquire picture data; the picture data is pre-correction picture data, which may be either initial picture data or post-adjustment picture data;
a transition area determining unit MU2 configured to obtain a feature boundary area BA based on the gray scale of pixels Pix in the picture data; the feature boundary area BA includes a plurality of feature pixel groups PixsA sequentially adjacent along a column direction DV; the feature pixel groups PixsA includes a first feature pixel Pix1 and a second feature pixel Pix2 which are adjacent in a same row; and a difference between a brightness of the first feature pixel Pix1 and a brightness of the second feature pixel Pix2 is greater than or equal to a brightness threshold Lset; the individual first feature pixels Pix1 in the same the feature boundary area BA are provided in the same column; the transition area determining unit MU2 is further configured to determine a transition area TA corresponding to the feature boundary area BA; the transition area TA corresponding to the feature boundary area BA includes at least a first transition area MTA, the first transition area MTA includes the individual first feature pixels Pix1 and/or the individual second feature pixels Pix2 of the feature boundary area BA;
a transition algorithm unit MU3 configured to correct gray scales of at least part of pixels Pix of the transition area TA corresponding to the feature boundary area BA, such that a difference between a brightness of the first feature pixel Pix1 after the correction and a brightness of the second feature pixel Pix2 after correction in the feature boundary area BA is less than a difference between a brightness of the first feature pixel Pix1 before correction and a brightness of the second feature pixel Pix2 before correction; and
a data outputting unit MU4 configured to drive the display panel PNL based on the result of correcting the gray scales of at least part of the pixels Pix of the transition area TA corresponding to the feature boundary area BA.

In some embodiments, the data handling unit DHU further includes a sub-pixel adjusting unit MU5. The data caching unit MU1 is configured to cache initial picture data. The sub-pixel adjusting unit MU5 is configured to adjust the arrangement sequence of the gray scales of at least some of sub-pixels of the initial picture data according to the sub-pixel arrangement of the display panel PNL in order to obtain the post-adjustment picture data; and the data caching unit MU1 is further configured to, according to the post-adjustment picture data of the sub-pixel adjusting unit MU5, update the initial picture data to the post-adjustment picture data. The transition area determining unit MU2 is configured to obtain a feature boundary area BA based on the gray scales of pixels Pix in the post-adjustment picture data.

In some embodiments, the transition area determining unit MU2 includes a data comparing unit MUA1 and a data recording and accumulating unit MUA2.

The data comparing unit MUA1 is configured to compare the brightness of two pixels adjacent to each other in the same row, and determine whether the two pixels adjacent to each other in the same row are considered as a feature pixel group PixsA; and the data recording and accumulating unit MUA2 is configured to record the number of feature pixel groups PixsA adjacent in the same row, and determine whether these feature pixel groups PixsA adjacent in the same row form a feature boundary area BA. For example, the data recording and accumulating Unit MUA2 is configured to record a data accumulation number n and to determine whether the data accumulation number n exceeds a feature number threshold Nset. Further, the data recording and accumulating unit MUA2 is also configured, after acquiring the feature boundary area BA, to record the feature boundary area BA. In the example of FIG. 14, the data comparing unit MUA1 may acquire the post-adjustment picture data from the data caching unit MU1, and acquire the feature boundary area BA based on the post-adjustment picture data.

In one embodiment of the present disclosure, the control component CTR may include a SOC (system-on-chip) board and a BCON (backlight control) board, and the SOC board is provided with a SOC chip; and the data handling unit DHU may be the SOC chip (system-on-chip) or a part of the SOC chip. The SOC chip may receive initial picture data and perform processing such as sub-pixel adjusting, transition area determination, and transition area correction on the initial picture data. Further, when the display device is a liquid crystal display device, the SOC chip may generate synchronous picture data and synchronous dimming data based on the picture data. The synchronous backlight data is used to be sent to the display panel PNL for displaying the picture. The synchronous dimming data is used to be sent to the MCU of the BCON board for controlling the duty cycles of the respective light areas of the backlight unit BLU. In some embodiments, the SOC chip may generate the synchronous dimming data and the synchronous picture data based on the picture data to be displayed.

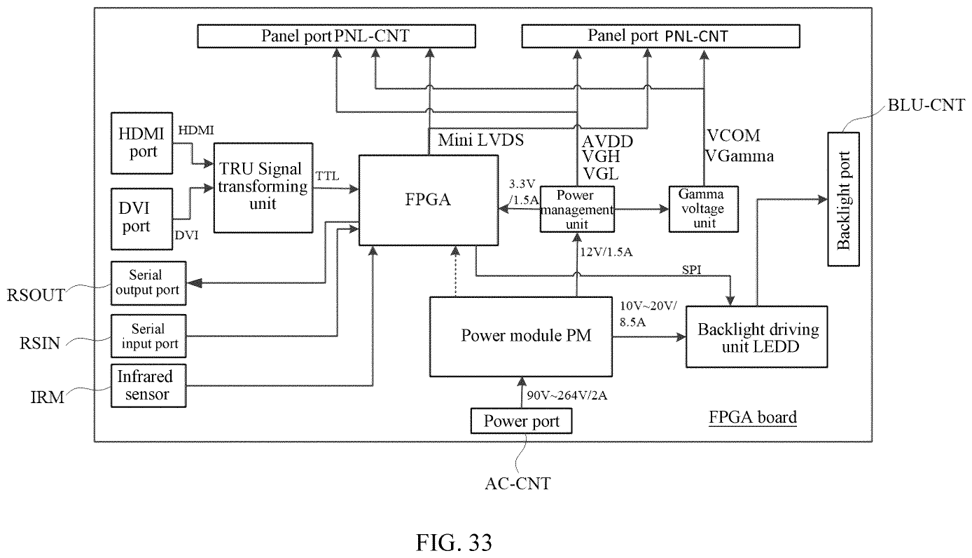

In another embodiment of the present disclosure, referring to FIG. 33, the control component CTR may include an FPGA (field programmable gate array) board, which may include an FPGA disposed on a circuit board. The data handling unit DHU may be the FPGA or a part of the FPGA. The FPGA may receive initial picture data and perform processing such as sub-pixel adjusting, transition area determination, and transition area correction on the initial picture data. Further, in a case where the display device is a liquid crystal display device, the FPGA may generate synchronous picture data and synchronous dimming data based on the picture data. The synchronous backlight data is used to be sent to the display panel PNL for displaying the screen. The synchronous dimming data is used to drive the backlight module BLU. In some embodiments, the FPGA may generate the synchronous dimming data and the synchronous picture data based on the picture data to be displayed.

In one example, a backlight driving unit LEDD is provided on the FPGA board, and the synchronous dimming data generated by the FPGA can be directly sent to the backlight driving unit LEDD, and the backlight driving unit LEDD sends the duty cycle data of the respective light areas to the microchip MIC to which the respective light areas are connected in accordance with the dimming data. In this way, it can avoid the asynchronous response of the display panel PNL and the backlight unit BLU caused by the MCU forwarding synchronous dimming data.

In one example, the circuit board of the FPGA board may also be provided with a power module PM, a power management unit PMIC, and a gamma voltage unit GMIC. The power module PM is configured to connect to an external power supply and to supply power to the power management unit PMIC and to the backlight driving unit LEDD. The power management unit PMIC is configured to supply a plurality of different power supply voltages to the liquid crystal display panel PNL and to supply power to the gamma voltage unit GMIC. The gamma voltage unit GMIC is configured to provide the liquid crystal display panel PNL with a common voltage VCOM and a gamma binding point voltage VGamma corresponding to respective gamma binding point gray scale. The FPGA is powered from the power module PM or the power management unit PMIC. In this way, the integrated board of the present disclosure can at least realize the functions of the screen driver boards, voltage boards and conversion boards in the related art, which may reduce the number of boards in the control component, thereby improving the integration of the control component and improving the assembly efficiency of the display device.

In one example, the circuit board of the FPGA board may also be provided with a panel port PNL-CNT for connecting to the liquid crystal display panel PNL and a backlight port BLU-CNT for connecting to the backlight unit BLU, as well as a power port AC-CNT for connecting to an external power supply. Depending on the distribution of the binding pads on the liquid crystal display panel PNL, the panel port may be one or more. For example, the panel port may include two ports. According to the distribution of the binding pads on the light board of the backlight unit BLU, the backlight port may be one or more. For example, nine backlight ports may be provided. Each backlight port may control one or more signal channels on the backlight unit BLU, with a plurality of light area LEDA, such as a plurality of light area LEDA controlled by sequentially cascaded microchip MICs, provided within each signal channel. In some embodiments, the panel ports and the backlight ports may be sequentially arranged pads or connectors for plugging, or other feasible structures.

In one example, the circuit board of the FPGA board is further provided with a communication module. The communication module is configured to implement at least one function of receiving a video signal, receiving a control signal, and sending a signal outward. The communication module includes at least one video signal port and a signal transforming unit TRU; the video signal port is configured to receive video signals and forward them to the signal transforming unit TRU; the signal transforming unit TRU is configured to transcode the video signals into initial picture data and forward the initial picture data to the FPGA.

In some embodiments, the signal transforming unit TRU may forward the picture data to the FPGA in the form of a TTL signal, e.g. in the form of a 24-channel TTL signal. It will be appreciated that in other examples of the present disclosure, the signal transforming unit TRU may also use other signals to forward the picture data, such as forwarding the picture data via SPI signals, LVDS signals, or Mini LVDS signals.

In some embodiments, the video signal port is selected from one or more of an HDMI port, a DVI port, a VGA port, and a DP port. In the example of FIG. 33, the HDMI port and the DVI port are provided on the FPGA board.

In some embodiments, the communication module may also include a serial communication port to enable the FPGA board card to communicate with an external device. Further, the serial communication port may include a serial input port RSIN and a serial output port RSOUT. The serial input port RSIN may receive external communication signals; for example, the serial input port RSIN is configured to receive external control signals and transmit them to the FPGA. The serial output port RSOUT is configured to send communication signals externally; for example, the serial output port RSOUT is configured to send outwardly signals generated by the FPGA. In one example, the serial input port RSIN and the serial output port RSOUT are RS-232 standard interfaces (asynchronous transmission standard interfaces).

In some embodiments, the serial input port RSIN may forward the communication signals to the FPGA and the FPGA may respond to the communication signals. For example, the debugging device may send a debugging signal (as a communication signal) to the FPGA via the serial input port RSIN, and the FPGA adjusts the display state of the display device in response to the debugging signal, such as adjusting the color temperature of the picture, adjusting the resolution, displaying the debugging interface, and the like. The serial output port RSOUT can receive the communication signal sent by the FPGA and forward it outward.

In some embodiments, the communication module further includes an infrared sensor IRM; the infrared sensor IRM is configured to receive an infrared signal while generating a control signal, and transmit the control signal to the FPGA. In other examples, the infrared sensor IRM may also send signals outwardly.

Embodiments of the present disclosure provide a display device, a control component thereof, and a driving method thereof, which are capable of eliminating jaggedness that may be visible in the light-dark demarcation vertical line when displaying a picture having a light-dark boundary, by making a transition area with a brightness transition between the light pattern and the dark pattern.

By way of example, the screen shown in FIG. 9-1 may be used as a verification picture. Referring to FIG. 9-1, the verification picture has a light pattern (dark area) and a dark pattern (light area), and the light-dark boundary area between the light pattern and the dark pattern has a light-dark demarcation vertical line FIGA and a light-dark demarcation vertical line FIGB (a line in the direction of columns). Referring to FIG. 9-1, the verification picture has two different light-dark boundary areas, the light-dark boundary area corresponding to the light-dark demarcation vertical line FIGA and the light-dark boundary area corresponding to the light-dark demarcation vertical line FIGB. In the light-dark boundary area corresponding to the light-dark demarcation vertical line FIGA, the light pattern is on the right and the dark pattern is on the left; in the light-dark boundary area corresponding to the light-dark demarcation vertical line FIGB, the light pattern is on the left and the dark pattern is on the right. The difference in gray scale or the difference in brightness between the light pattern and the dark pattern is greater than a threshold requirement of the embodiment of the present disclosure, such as the difference in gray scale is greater than a feature gray scale threshold. For example, the light pattern is a white pattern with a gray scale of 255; the dark pattern is a black pattern with a gray scale of 0. The brightness threshold is set to 50 nits, and the feature number threshold is set to 5.

FIG. 10 illustrates a grayscale state of the initial picture data of the verification pattern at the light-dark boundary area corresponding to the light-dark demarcation vertical line FIGA. In FIG. 10, the pixel of high gray scale is covered with a light color pattern, and the pixel of low gray scale is covered with a dark color pattern. According to FIG. 10, it can be seen that a light-dark demarcation vertical line is between two columns of pixels in the boundary area BAO, and individual pixels on the left side of the light-dark demarcation vertical line are of low gray scales to be a part of the dark pattern; and individual pixels on the right side of the light-dark demarcation vertical line are of high gray scales to be a part of the light pattern.

FIG. 11 illustrates a grayscale state of the initial picture data of the verification pattern at the light-dark boundary area corresponding to the light-dark demarcation vertical line FIGB. In FIG. 11, the pixel of high gray scale is covered with a light color pattern, and the pixel of low gray scale is covered with a dark color pattern. According to FIG. 11, it can be seen that a light-dark demarcation vertical line is between two columns of pixels in the demarcation area BAO, and individual pixels on the right side of the light-dark demarcation vertical line are of low gray scales to be a part of the dark pattern; and individual pixels on the left side of the light-dark demarcation vertical line are of high gray scales to be a part of the light pattern.

After the initial pattern data of the verification pattern is input to the display device of the present disclosure, the display device of the present disclosure can cause the initial picture data to change into the to-be-displayed picture data, and the display panel displays a screen picture based on the to-be-displayed picture data. In other words, from the perspective of the picture data, the display device and the control component and driving method thereof according to the present disclosure can cause the initial picture data to change into the to-be-displayed picture data; and from the perspective of the final display result, the display device and the control component and driving method thereof according to the present disclosure can display the verification picture as a screen picture. Both the grayscales of individual pixels of the screen picture and the to-be-displayed picture data can be characterized as follows: the grayscales of at least one column of pixels in the light-dark boundary area corresponding to the light-dark demarcation vertical line FIGA and the light-dark boundary area corresponding to the light-dark demarcation vertical line FIGB of the verification picture are changed, so that the brightness (or the grayscale) between the dark picture and the light picture is transitioned through the column of the pixels that have been changed. The area in which these changed columns of pixels are located is referred to as a transition area in the embodiments of the present disclosure. According to embodiments of the present disclosure, the transition area may take many different forms. Satisfying any one of these forms is considered to employ the display device and its control component and driving method according to the embodiments of the present disclosure. These methods include selecting one or more columns of pixels to form the transition area on the dark picture side of the light-dark demarcation vertical line of the verification picture, selecting one or more columns of pixels to form the transition area on the light picture side of the light-dark demarcation vertical line of the verification picture, and selecting at least one column of pixels to form the transition area on each of the light picture side and the dark picture side of the light-dark demarcation vertical line of the verification picture.

As an example, FIG. 21 illustrates a scheme of selecting one column of pixels (covered by a grid pattern) on the light picture side of the light-dark demarcation vertical line to form the transition area TA. In the final effect, the pixels in the transition area are adjacent to the dark pattern and have a reduced brightness or gray scale compared to the verification pattern, reduced compared to the remaining part of the light pattern, but still higher than the adjacent dark pattern. For example, the light pattern has a gray scale of 255 and the dark pattern has a gray scale of 0. The pixels in the transition area may have a gray scale of 127.

As an example, FIG. 22 illustrates a scheme of selecting two columns of pixels (covered by a grid pattern) on the light picture side of the light-dark demarcation vertical line to form a transition area TA. In the final effect, the pixels in the transition area are adjacent to the dark pattern and have a reduced brightness or gray scale compared to the verification pattern, reduced compared to the remaining part of the light pattern, but still higher than the adjacent dark pattern. Of the two columns of pixels in the transition area, the column of pixels closer to the dark pattern has a lower gray scale and the pixels closer to the light pattern have higher gray scales. For example, the light pattern has a gray scale of 255 and the dark pattern has a gray scale of 0. The pixels closer to the light pattern in the transition area have a gray scale of 170 and the pixels closer to the dark pattern have a gray scale of 85.

As an example, FIG. 23 illustrates a scheme of selecting three columns of pixels (covered by a grid pattern) on the light picture side of the light-dark demarcation vertical line to form a transition area TA. In the final effect, the pixels in the transition area are adjacent to the dark pattern and have a reduced brightness or gray scale compared to the validation pattern, reduced compared to the remaining part of the light pattern, but are still higher than the adjacent dark pattern. Of the three columns of pixels in the transition area, the column of pixels closer to the dark pattern has the lowest gray scale and the pixels closer to the light pattern have the highest gray scales. For example, the light pattern has a gray scale of 255 and the dark pattern has a gray scale of 0. In the transition area, the pixels closer to the light pattern have a gray scale of 191, the pixels in the middle column have a gray scale of 127, and the pixels closer to the dark pattern have a gray scale of 64.

As an example, FIG. 25 illustrates a scheme of selecting a column of pixels (covered by a grid pattern) on the dark picture side of a light-dark demarcation vertical line to form a transition area TA. In the final effect, the pixels in the transition area are adjacent to the light pattern and have an increased brightness or gray scale compared to the verification pattern, increased compared to the remaining part of the dark pattern, but are still lower than the adjacent light pattern. For example, the light pattern has a gray scale of 255 and the dark pattern has a gray scale of 0. The pixels in the transition area may have a gray scale of 127.

As an example, FIG. 26 illustrates a scheme of selecting two columns of pixels (covered by a grid pattern) on the dark picture side of a light-dark demarcation vertical line to form a transition area TA. In the final effect, the pixels in the transition area are adjacent to the light pattern and have an increased brightness or gray scale compared to the verification pattern, increased compared to the remaining part of the dark pattern, but are still lower than the adjacent light pattern. Of the two columns of pixels in the transition area, the column of pixels closer to the dark pattern has a lower gray scale and the pixels closer to the light pattern have a higher gray scale. For example, the light pattern has a gray scale of 255 and the dark pattern has a gray scale of 0. In the transition area, the pixels closer the light pattern have a gray scale of 170 and the pixels closer the dark pattern have a gray scale of 85.

As an example, FIG. 27 illustrates a scheme of selecting three columns of pixels (covered by a grid pattern) on the dark picture side of a light-dark demarcation vertical line to form a transition area TA. In the final effect, the pixels in the transition area are adjacent to the dark pattern and have an increased brightness or gray scale compared to the verification pattern, increased compared to the remaining part of the dark pattern, but are still lower than the adjacent light pattern. Of the three columns of pixels in the transition area, the column of pixels closer to the dark pattern has the lowest gray scale and the pixels closer to the light pattern have the highest gray scale. For example, the light pattern has a gray scale of 255 and the dark pattern has a gray scale of 0. In the transition area, the pixels closer to the light pattern have a gray scale of 191, the pixels in the middle column have a gray scale of 127, and the pixels closer to the dark pattern have a gray scale of 64.

As an example, FIG. 28 illustrates a scheme of selecting two columns of pixels (covered by a grid pattern) on each side of a light and dark demarcation vertical line to form a transition area TA. In the final effect, the pixels in the transition area are flanked by a dark pattern and a light pattern, respectively, and have a brightness or gray scale that is increased compared to the remaining part the dark pattern and decreased compared to the remaining part of the light pattern. Of the four columns of pixels in the transition area, the gray scale of the pixels in each column decreases sequentially along the direction from the light pattern to the dark pattern. For example, the gray scale of the light pattern is 255 and the gray scale of the dark pattern is 0. In the transition area, the pixel closest to the light pattern has a gray scale of 204, the pixel next closest to the light pattern has a gray scale of 153, the pixel next closest to the dark pattern has a gray scale of 102, and the pixel closest to the dark pattern has a gray scale of 51. It is to be noted that, although the individual steps of the driving method of the present disclosure is depicted in a particular sequence in the accompanying figures, it is not required or implied that the steps must be performed in that particular sequence, or that all of the steps shown must be performed to achieve the desired result. Additional or alternatively, certain steps may be omitted, multiple steps may be combined into one step for execution, and/or one step may be decomposed into multiple steps for execution, etc.

Other embodiments of the present disclosure will be readily apparent to those skilled in the art upon consideration of the specification and practice of the disclosure herein. The present application is intended to cover any variations, uses, or adaptations of the present disclosure that follow the general principles of the present disclosure and include common knowledge or customary technical means in the art not disclosed herein. The specification and embodiments are to be regarded as exemplary only, and the true scope and spirit of the present disclosure is indicated by the appended claims.

1. A display device capable of displaying a target picture based on picture data of a received initial picture; wherein the display device is configured to: adjust, when the initial picture comprises at least one feature boundary area, brightnesses of at least some pixels of the feature boundary area to generate a target picture;
wherein the feature boundary area comprises a plurality of feature pixel groups sequentially adjacent along a column direction; the feature pixel group comprises a first feature pixel and a second feature pixel which are adjacent in a same row, and a brightness difference between the first feature pixel and the second feature pixel is greater than or equal to a brightness threshold; and wherein individual first feature pixels in a same feature boundary area are provided in a same column; and
a difference between a brightness of the first feature pixel and a brightness of the second feature pixel in the target picture at positions corresponding one-to-one with pixels in the feature boundary area of the initial picture is less than a difference between a brightness of the first feature pixel and a brightness of the second feature pixel in the initial picture.

2. The display device according to claim 1, wherein the display device comprises a display panel; the display panel comprises a plurality of pixels distributed in an array, and any one of the pixels comprises a plurality of sub-pixels of different colors disposed adjacent along a row direction; individual sub-pixels are arranged in a plurality of columns of sub-pixels; and in any one of the columns of sub-pixels, two adjacent sub-pixels are different in color.

3. The display device according to claim 1, wherein the display device is configured in at least one of the following manners:
a number of feature pixel groups in any one of the feature boundary areas is not less than a feature number threshold; and the feature number threshold is not less than 5;
the brightness threshold is not less than 50 nits;
gray scales of the first feature pixels are same and gray scales of the second feature pixels are same in at least one of the feature boundary areas;
the display device is a spliced display device; the display device comprises a plurality of display modules arranged in matrix and spliced together, and the display modules comprise display panels; or
the brightness difference between the first feature pixel and the second feature pixel is a theoretical maximum brightness difference between the first feature pixel and the second feature pixel.

4. (canceled)

5. The display device according to claim 1, wherein gray scales for individual sub-pixels of the first feature pixel are same and gray scales for individual sub-pixels of the second feature pixel are same in the initial picture.

6-7. (canceled)

8. The display device according to claim 1, wherein, on at least one side of the display panel, a distance between an edge of a display area of the display panel and an edge of the display panel on this side is not greater than 2 millimeters.

9. (canceled)

10. A control component for a display device, the display device further comprises a display panel; the display panel comprises a plurality of pixels distributed in an array, and any one of the pixels comprises a plurality of sub-pixels of different colors disposed adjacent along a row direction; individual sub-pixels are arranged in a plurality of columns of sub-pixels; and in any one of the columns of sub-pixels, two adjacent sub-pixels are different in color;
the control component comprises a processor, a memory and an executable program stored on the memory and capable of being run by the processor, wherein when the processor runs the executable program, the processor is configured to:
obtain picture data;
obtain a feature boundary area based on gray scales of pixels in the picture data; the feature boundary area comprises a plurality of feature pixel groups sequentially adjacent along a column direction; the feature pixel group comprises a first feature pixel and a second feature pixel which are adjacent in a same row and a brightness difference between the first feature pixel and the second feature pixel is greater than or equal to a brightness threshold; individual first feature pixels in a same feature boundary area are provided in a same column;
determine a transition area corresponding to the feature boundary area; the transition area corresponding to the feature boundary area comprises at least a first transition area, the first transition area comprises at least one of individual first feature pixels or individual second feature pixels of the feature boundary area;
correct gray scales of at least some of pixels of the transition area corresponding to the feature boundary area, such that, after correction, a difference between a brightness of the first feature pixel and a brightness of the second feature pixel in the feature boundary area is less than a difference between a brightness of the first feature pixel before the correction and a brightness of the second feature pixel before the correction; and
drive the display panel based on a result of correcting the gray scales of at least some of the pixels in the transition area corresponding to the feature boundary area.

11. The control component according to claim 10, wherein when the processor runs the executable program, the processor is further configured to:
compare brightnesses of two pixels adjacent in a same row to determine whether the two pixels adjacent in the same row are considered as a feature pixel group; and
record a number of feature pixel groups adjacent in a same column, and determine whether these feature pixel groups adjacent in the same column form a feature boundary area.

12. The control component according to claim 10, wherein when the processor runs the executable program, the processor is further configured to:
cache the initial picture data;
obtain post-adjustment picture data by adjusting an arrangement sequence of gray scales of at least some of the sub-pixels in the initial picture data according to an arrangement of the sub-pixels of the display panel;
update the initial picture data to the post-adjustment picture data based on the post-adjustment picture data of the sub-pixel adjusting unit; and
obtain the feature boundary area based on gray scales of pixels in the post-adjustment picture data.

13. (canceled)

14. A method for driving a display device, wherein a display panel of the display device comprises a plurality of pixels distributed in an array, and any one of the pixels comprises a plurality of sub-pixels of different colors disposed adjacent along a row direction; individual sub-pixels are arranged in a plurality of columns of sub-pixels; and in any one of the sub-pixel columns, two adjacent sub-pixels are different in color;
the method for driving the display device comprises:
obtaining picture data;
obtaining a feature boundary area based on gray scales of pixels in the picture data; the feature boundary area comprises a plurality of feature pixel groups sequentially adjacent along a column direction; the feature pixel group comprises a first feature pixel and a second feature pixel which are adjacent in a same row, and a brightness difference between the first feature pixel and the second feature pixel is greater than or equal to a brightness threshold; individual first feature pixels in a same feature boundary area are provided in a same column;
determining a transition area corresponding to the feature boundary area; the transition area corresponding to the feature boundary area comprises at least a first transition area, the first transition area comprises at least one of individual first feature pixels or individual second feature pixels of the feature boundary area;
correcting gray scales of at least some of pixels of the transition area corresponding to the feature boundary area, such that, after correction, a difference between a brightness of the first feature pixel and a brightness of the second feature pixel in the feature boundary area is less than a difference between a brightness of the first feature pixel before the correction and a brightness of the second feature pixel before the correction; and
driving the display panel based on a result of correcting the gray scales of at least some of the pixels in the transition area corresponding to the feature boundary area.

15. The method according to claim 14, wherein a number of feature pixel groups in any one of the feature boundary areas is not less than a feature number threshold; or
a number of feature pixel groups in any one of the feature boundary is not less than 5; and the brightness threshold is in the range of 40 to 1000 nits.

16. (canceled)

17. The method according to claim 14, wherein obtaining the feature boundary area based on the gray scales of the pixels in the picture data further comprises:
causing the feature boundary area to have a homochromatic contiguous area, the homochromatic contiguous area is adjacent to at least one column of pixels in the feature boundary area and has same color and gray scale as the at least one column of pixels in the feature boundary area;
determining the transition area corresponding to the feature boundary area comprises:
determining the transition area corresponding to the feature boundary area based on the feature boundary area and the homochromatic contiguous area of the feature boundary area.

18. The method according to claim 17, wherein the homochromatic contiguous area of the feature boundary area comprises at least one of a first homochromatic contiguous area and a second homochromatic contiguous area;
the first homochromatic contiguous area comprises first homochromatic pixel groups corresponding one-to-one with individual feature pixel groups of the feature boundary area; the first homochromatic pixel group is adjacent to the first feature pixel of a corresponding feature pixel group in a same row and is of same color and grayscale as the first feature pixel, and the first homochromatic pixel group comprises one or more pixels;
the second homochromatic contiguous area comprises second homochromatic pixel groups corresponding one-to-one with individual feature pixel groups of the feature boundary area; the second homochromatic pixel group is adjacent to the second feature pixel of a corresponding the feature pixel group in a same row and is of same color and gray scale as the second feature pixel, and the second homochromatic pixel group comprises one or more pixels.

19. The method according to claim 18, wherein, when the homochromatic contiguous area of the feature boundary area comprises a first homochromatic contiguous area, determining the transition area corresponding to the feature boundary area comprises:
determining that the transition area corresponding to the feature boundary area comprises individual first feature pixels of the feature boundary area;
correcting the gray scales of at least some of the pixels of the transition area corresponding to the feature boundary area comprises:
obtaining corrected gray scales of the individual first feature pixels of the feature boundary area by reducing gray scales of the individual first feature pixels; the corrected gray scale of the first feature pixel is greater than a gray scale of the second feature pixel in a same feature pixel group.

20. The method according to claim 19, wherein correcting the gray scales of at least some of the pixels of the transition area corresponding to the feature boundary area comprises:
obtaining corrected gray scales Gn(Pix1) of individual first feature pixels of the feature boundary area by reducing the gray scales of the individual first feature pixels, and
$$G ( Pix 2 ) + 0 . {3}^{*} ( G ( P i x 1 ) - G ( P i x 2 ) ) < G n ( Pix 1 ) < G ( Pix 1 ) - {0.3}^{*} ( G ( P i x 1 ) - G ( P i x 2 ) ) ;$$
wherein G(Pix1) is a gray scale of the first feature pixel; and G(Pix2) is a gray scale of the second feature pixel.

21. The method according to claim 18, wherein, when the homochromatic contiguous area of the feature boundary area comprises a first homochromatic contiguous area and the first homochromatic contiguous area comprises a plurality of columns of pixels, determining the transition area corresponding to the feature boundary area comprises:
determining that the transition area corresponding to the feature boundary area comprises a first transition area and a second transition area; the first transition area comprises individual first feature pixels of the feature boundary area; and the second transition area comprises at least one column of pixels in the first homochromatic contiguous area adjacent to the first transition area, and at least one column of pixels in the first homochromatic contiguous area does not belong to the second transition area;
correcting the gray scales of at least some of the pixels in the transition area corresponding to the feature boundary area comprises:
obtaining corrected gray scales of individual pixels by reducing the gray scales of the individual pixels in the transition area, wherein the corrected gray scales of the individual pixels in any row in the transition area decreases sequentially along a direction pointing from the first homochromatic contiguous area to the feature boundary area, and the corrected gray scale of the first feature pixel is greater than a gray scale of the second feature pixel.

22. The method according to claim 21, wherein correcting the gray scales of at least some of the pixels in the transition area corresponding to the feature boundary area comprises:
determining a corrected gray scale of any one pixel in the transition area according to the following formula:
$$Gn ( q ) = round ( G ( Pix 1 ) - {q}^{*} ( ( G ( P i x 1 ) - G ( P i x 2 ) ) / ( Q + 1 ) ) ;$$
wherein Gn(q) is a corrected gray scale of a qth column of pixels P(q) in the transition area along a direction pointing from the first homochromatic contiguous area to the feature boundary area; G(Pix1) is a gray scale of the first feature pixel which is in a same row with pixel P(q); G(Pix2) is a gray scale of the second feature pixel which is in a same row with pixel P(q); Q is a number of columns of pixels comprised in the transition area, Q is a positive integer not less than 2; and q is a positive integer from 1 to Q.

23. The method according to claim 18, wherein, when the homochromatic contiguous area of the feature boundary area comprises a second homochromatic contiguous area, determining the transition area corresponding to the feature boundary area comprises:
determining that the transition area corresponding to the feature boundary area comprises individual second feature pixels of the feature boundary area;
correcting the gray scales of at least some of the pixels of the transition area corresponding to the feature boundary area comprises:
obtaining corrected gray scales of the individual second feature pixels by increasing gray scales of the individual second feature pixels of the feature boundary area; the corrected gray scale of the second feature pixel is less than a gray scale of the first feature pixel in a same feature pixel group.

24. The method according to claim 23, wherein correcting the gray scales of at least some of the pixels of the transition area corresponding to the feature boundary area comprises:
obtaining corrected gray scales Gn(Pix2) of individual second feature pixels of the feature boundary area by increasing gray scales of the individual second feature pixels, and
$$G ( Pix 2 ) + 0 . {3}^{*} ( G ( P i x 1 ) - G ( P i x 2 ) ) < G n ( Pix 2 ) < G ( Pix 1 ) - {0.3}^{*} ( G ( P i x 1 ) - G ( P i x 2 ) ) ;$$
wherein G(Pix1) is a gray scale of the first feature pixel; and G(Pix2) is a gray scale of the second feature pixel.

25. The method according to claim 18, wherein, when the homochromatic contiguous area of the feature boundary area comprises a second homochromatic contiguous area and the second homochromatic contiguous area comprises a plurality of columns of pixels, determining the transition area corresponding to the feature boundary area comprises:
determining that the transition area corresponding to the feature boundary area comprises a first transition area and a third transition area; the first transition area comprises individual second feature pixels of the feature boundary area; and the third transition area comprises at least one column of pixels in the second homochromatic contiguous area adjacent to the first transition area, and at least one column of pixels in the second homochromatic contiguous area does not belong to the third transition area;
correcting the gray scales of at least some of the pixels in the transition area corresponding to the feature boundary area comprises:
obtaining corrected gray scales of individual pixels in the transition area by increasing gray scales of the individual pixels, and the corrected gray scales of the individual pixels in any row of the transition area increases sequentially along a direction pointing from the second homochromatic contiguous area to the feature boundary area, and the corrected gray scale of the second feature pixel is less than a gray scale of the first feature pixel.

26. The method according to claim 25, wherein correcting the gray scales of at least some of the pixels in the transition area corresponding to the feature boundary area comprises:
determining a corrected gray scale for any one pixel in the transition area according to the following formula:
$$Gn ( t ) = round ( G ( Pix 1 ) - {t}^{*} ( ( G ( P i x 1 ) - G ( P i x 2 ) ) / ( T + 1 ) ) ;$$
wherein Gn(t) is a corrected gray scale of a t-th column of pixels P(t) in the transition area along a direction pointing from the second homochromatic contiguous area to the feature boundary area; G(Pix1) is a gray scale of the first feature pixel which is in a same row with pixel P(t); G(Pix2) is a gray scale of the second feature pixel which is in a same row with pixel P(t); T is a number of columns of pixels comprised in the transition area, T is a positive integer not less than 2; and t is a positive integer from 1 to T.
